(19) United States
(12) Patent Application Publication
(10) Pub. No.: US 2024/0363724 A1
(43) Pub. Date: Oct. 31, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventor: Ding-Kang Shih, Hsinchu (TW)

(73) Assignee: Taiwan Semiconductor Manufacturing Company, Ltd., Hsinchu (TW)

(21) Appl. No.: 18/307,025

(22) Filed: Apr. 26, 2023

(51) Int. Cl. H01L 29/66; H01L 21/02; H01L 21/311; H01L 21/768; H01L 23/535; H01L 29/06; H01L 29/423; H01L 29/775

(52) U.S. Cl. CPC H01L 29/66439; H01L 21/02164; H01L 21/02236; H01L 21/02255; H01L 21/02532; H01L 21/31111; H01L 21/76895; H01L 23/535; H01L 29/0673; H01L 29/42392; H01L 29/66545; H01L 29/66553; H01L 29/775

(57) ABSTRACT

A method of manufacturing a semiconductor device includes: forming a stack of semiconductor layers and sacrificial layers alternately arranged over a substrate; patterning the stack to form a stacking structure on the substrate; disposing a sacrificial gate structure on the substrate, where the sacrificial gate structure covers a portion of the stacking structure; removing portions of the stacking structure not overlapped with the sacrificial gate structure; disposing source/drain regions at opposite sides of the sacrificial gate structure, where the semiconductor layers in the remained stacking structure connect between the source/drain regions; removing the sacrificial gate structure and rest of the sacrificial layers to form a cavity accessibly revealing the semiconductor layers; forming a semiconductor material to cover the semiconductor layers; performing a thermal process to transfer the semiconductor material into a Si-containing layer and a Ge-containing layer, where the Si-containing layer is disposed over the semiconductor layers, and the Ge-containing layer is interposed between the Si-containing layer and the semiconductor layers; and forming a gate structure in the cavity and over the remained stacking structure.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. However, such scaling has also introduced increased complexity to the semiconductor manufacturing process. Thus, the realization of continued advances in ICs and devices calls for similar advances in semiconductor manufacturing processes and technology.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6A, 7A, 8A, 9A, 10A, 11A, 12A, 13A, 14A, 15A, 16A, and 17A are schematic three-dimensional views of various stages in a manufacturing method of a semiconductor device in accordance with some embodiments of the disclosure.

FIGS. 6B, 7B, 8B, 9B, 10B, 11B, 12B, 13B, 14B, 15B, 16B, and 17B are schematic, enlarged cross-sectional views of a portion of the semiconductor device outlined in a dashed box W as shown in FIGS. 6A, 7A, 8A, 9A, 10A, 11A, 12A, 13A, 14A, 15A, 16A, and 17A, respectively.

FIG. 18A is a schematic three-dimensional view of a semiconductor device in accordance with some other embodiments of the disclosure.

FIG. 18B is a schematic, enlarged cross-sectional view of a portion of the semiconductor device outlined in a dashed box V as shown in FIG. 18A.

FIG. 19A and FIG. 19B are a flow chart illustrating a method for manufacturing a portion of a semiconductor device in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third” and the like, may be used herein for ease of description to describe similar or different element(s) or feature(s) as illustrated in the figures, and may be used interchangeably depending on the order of the presence or the contexts of the description.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

It should be appreciated that the following embodiment(s) of the disclosure provides applicable concepts that can be embodied in a wide variety of specific contexts. The specific embodiment(s) discussed herein is merely illustrative and is related to a semiconductor device including a Ge-containing layer covering a channel, and is not intended to limit the scope of the disclosure. In accordance with some embodiments, the semiconductor device includes a substrate, a device formed over the substrate, and an interconnect over the substrate and electrically coupled to the device, where the device includes a channel region covering by a Ge-containing layer, a gate structure standing on the Ge-containing layer over the channel region, and a pair of source/drain region arranged at two opposite sides of the gate structure. In the case, due to the Ge-containing layer covering over the channel region (e.g., a silicon channel), the threshold voltage (Vth) of the device (e.g., PMOS) can be greatly reduced. In addition, due to the Ge-containing layer covering over the channel region (e.g., a silicon channel), the compressive strain is further provided to the channel region of the device (e.g., PMOS), thereby enhancing hole mobility of the channel region.

However, the semiconductor device(s) described in the disclosure may be a field-effect transistor (FET), such as a planar FET, a tunnel field-effect transistor (TFET), a fin-type FET (FinFET), a gate all around (GAA) transistor, or a nanowire transistor. In accordance with some embodiments, the semiconductor device(s) may be or include a portion of a planar FET and/or a TFET device, which may include a silicon body standing on a substrate, and a gate is standing on the silicon body (i.e., the channel region) providing control from a top side of the channel region. In accordance with some embodiments, the semiconductor device(s) may be or include a portion of a finFET device, which may include a thin (vertical) fin of silicon body on a substrate, and a gate is wrapped around the fin (i.e., the channel region) providing control from three sides of the channel region. In accordance with some embodiments, the semiconductor device(s) is or includes a portion of a nanostructure transistor device. The nanostructure transistor device may include a GAA transistor device, a nanosheet transistor or a nanowire transistor, which may include a gate structure wrapping around (e.g., engaging) the perimeter of one or more nanostructures (i.e., channel regions) for improved control of channel current flow.

In some embodiments, one or more semiconductor structures in the semiconductor device(s) may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer is formed over a substrate and patterned using a photolithography process, spacers are formed alongside the patterned sacrificial layer using a self-aligned process, and the sacrificial layer is then removed, and the remaining spacers may then be used to pattern the GAA structure.

In some embodiments, the semiconductor device(s) is formed on bulk silicon substrates. Still, the semiconductor device(s) may be formed on a silicon-on-insulator (SOI) substrate, a germanium-on-insulator (GOI) substrate, a silicon germanium substrate, or a Group III-V semiconductor substrate. Also, in accordance with some embodiments, the silicon substrate may include other conductive layers or other semiconductor elements, such as transistors, diodes, passive components, or the like. The embodiments are not limited in this context. The semiconductor device(s) may be included in microprocessors, memories, and/or other integrated circuits (IC). Accordingly, it is understood that additional processes may be provided before, during, and after the illustrated method, and that some other processes may only be briefly described herein. Also, the structures illustrated in the drawings are simplified for a better understanding of the concepts of the disclosure. For example, although the figures illustrate the structure of the semiconductor device(s), it is understood the semiconductor device(s) may be part of an IC that further includes a number of other devices such as resistors, capacitors, inductors, fuses, etc.

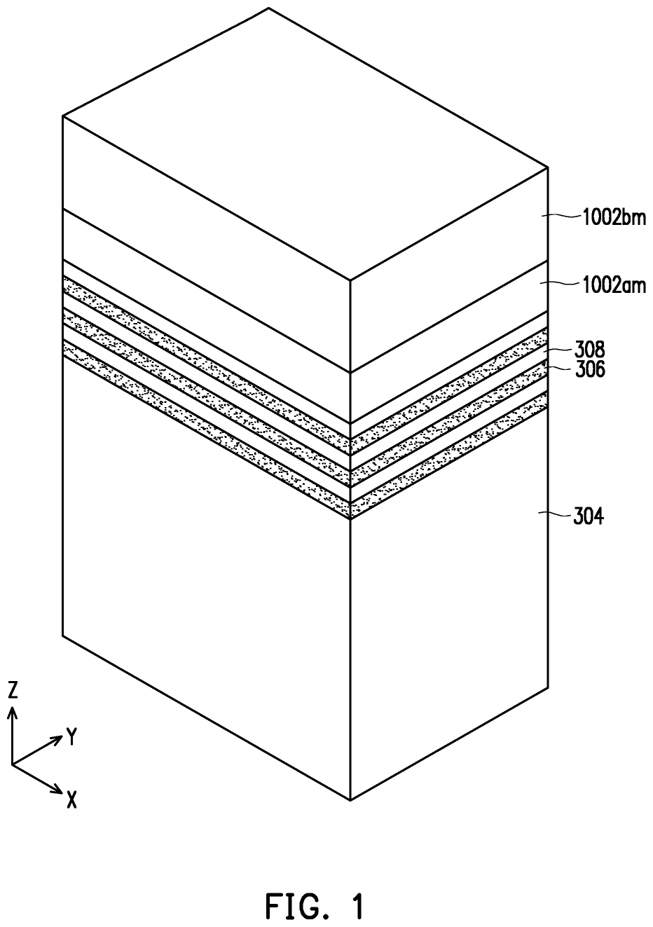

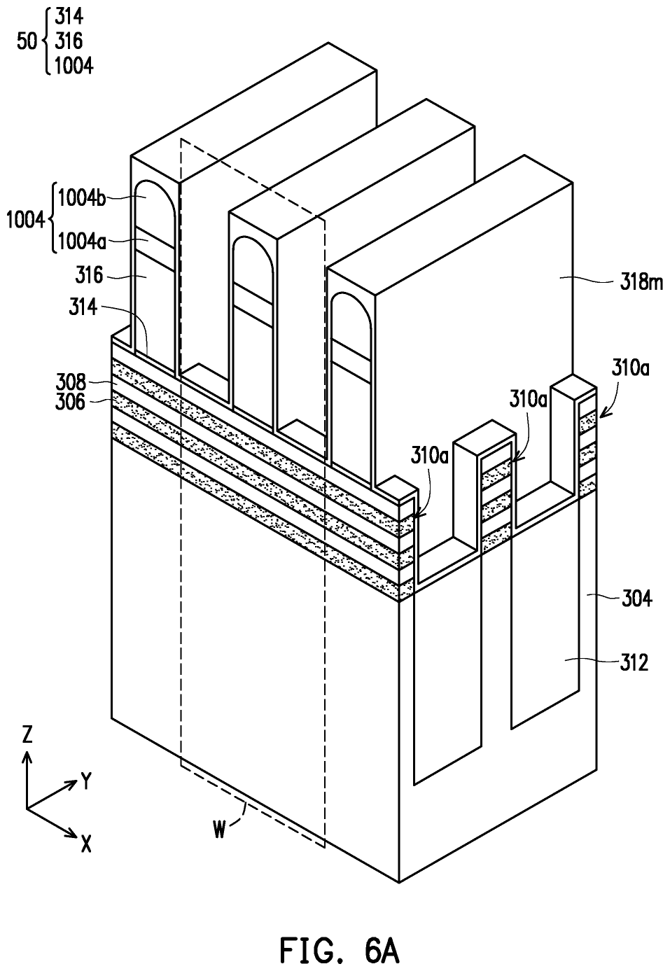

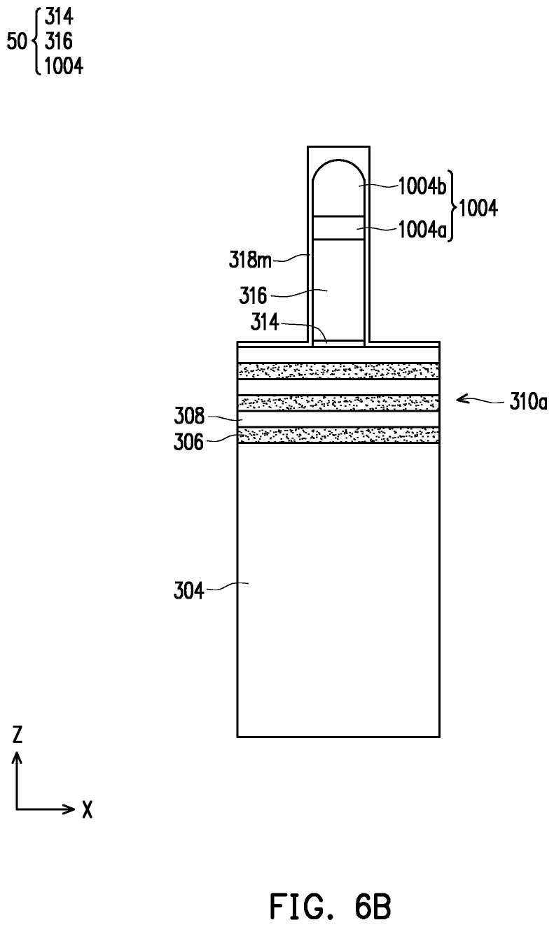

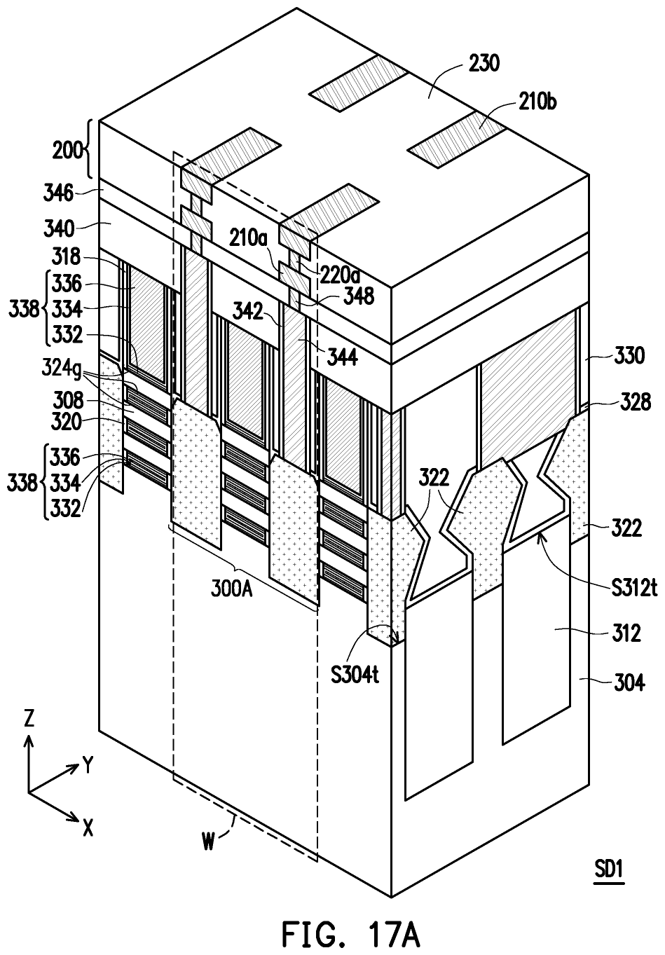

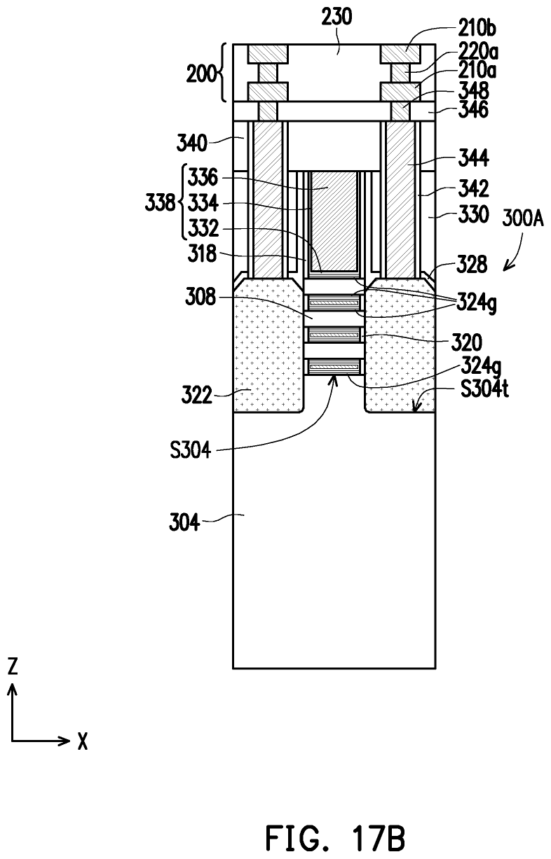

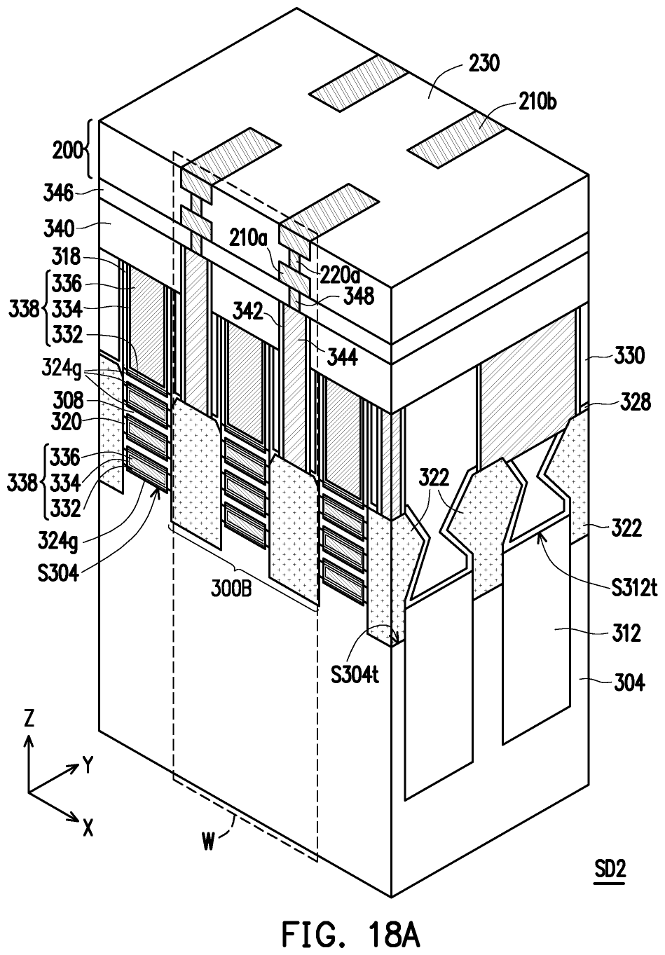

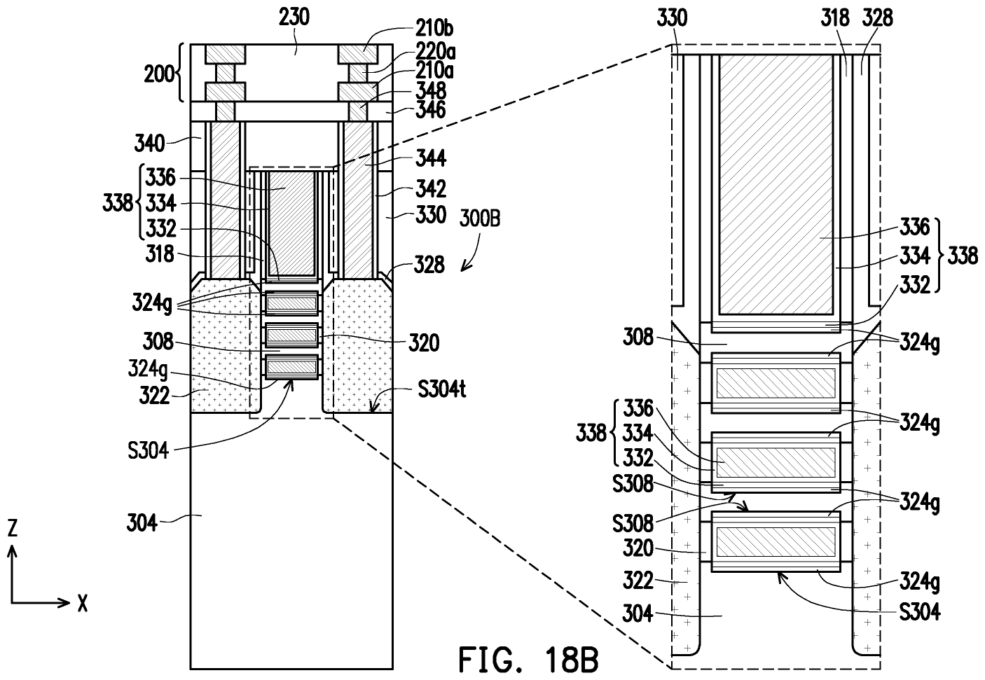

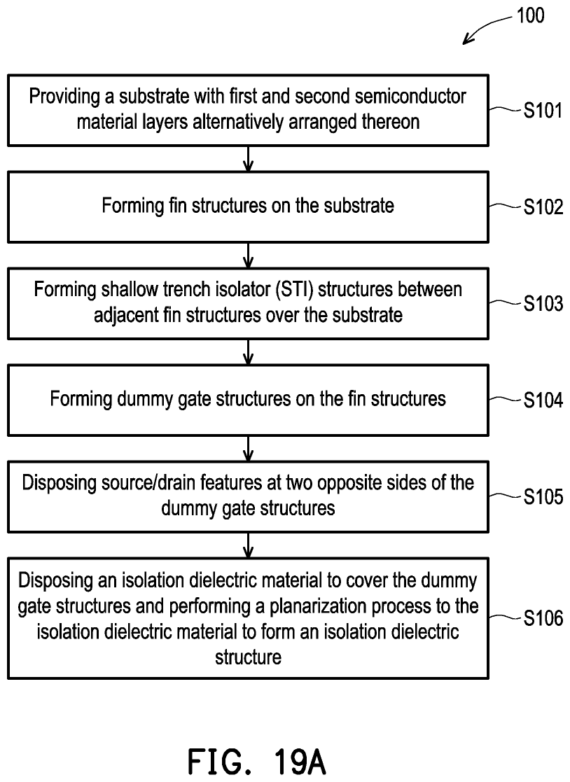

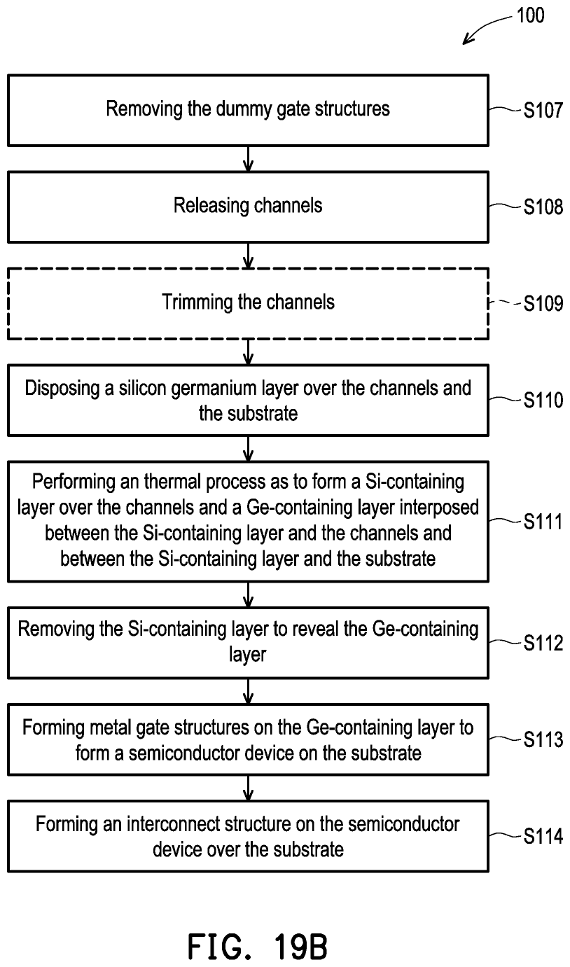

FIGS. 1, 2, 3, 4, 5, 6A, 7A, 8A, 9A, 10A, 11A, 12A, 13A, 14A, 15A, 16A, and 17A are schematic three-dimensional views of various stages in a manufacturing method of a semiconductor device SD1 in accordance with some embodiments of the disclosure. FIGS. 6B, 7B, 8B, 9B, 10B, 11B, 12B, 13B, 14B, 15B, 16B, and 17B are schematic, enlarged cross-sectional views of a portion of the semiconductor device SD1 outlined in a dashed box W as shown in FIGS. 6A, 7A, 8A, 9A, 10A, 11A, 12A, 13A, 14A, 15A, 16A, and 17A, respectively. FIG. 19A and FIG. 19B are a flow chart illustrating a method for manufacturing a portion of a semiconductor device (e.g., SD1 in FIGS. 17A-17B or SD2 in FIGS. 18A-18B) in accordance with some embodiments of the disclosure. In embodiments, the manufacturing method is part of a wafer level packaging process. It is to be noted that the process steps described herein cover a portion of the manufacturing processes used to fabricate the semiconductor device involving a Ge-containing layer covering a channel region included in a transistor. The embodiments are intended to provide further explanations but are not used to limit the scope of the disclosure. In the disclosure, it should be appreciated that the illustration of components throughout all figures is schematic and is not in scale. The elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, in the drawings are illustrated the orthogonal axes (X, Y and Z) of the Cartesian coordinate system according to which the views are oriented; however, the disclosure is not specifically limited thereto.

Referring to FIG. 1, in some embodiments, a stack of first and second semiconductor layers (306 and 308) may be formed on a semiconductor substrate 304, in accordance with a step S101 of a method 100 in FIGS. 19A-19B. In some embodiments, the semiconductor substrate 304 includes a crystalline silicon substrate or a bulk silicon substrate (e.g., wafer). In some embodiments, the semiconductor substrate 304 is made of a suitable elemental semiconductor (e.g., germanium), a suitable compound semiconductor (e.g., gallium arsenide, silicon carbide, indium arsenide, or indium phosphide), a suitable alloy semiconductor (e.g., silicon germanium carbide, gallium arsenic phosphide, or gallium indium phosphide), and/or the like. In some embodiments, the semiconductor substrate 304 includes a SOI substrate. The semiconductor substrate 304 may include various doped regions (not individually shown) doped with p-type or n-type dopants, where the doped regions may be configured for an n-type FET (nFET), or alternatively, configured for a p-type FET (pFET).

The first semiconductor layers 306 and the second semiconductor layers 308 may be alternately stacked upon one another (e.g., along a direction Z) to form the stack (e.g., a stacking structure) over the semiconductor substrate 304. The first semiconductor layers 306 may be considered sacrificial layers in the sense that they are removed in the subsequent process. In some embodiments, the bottommost one of the first semiconductor layers 306 is formed on the semiconductor substrate 304, with the remaining second and first semiconductor layers (308 and 306) alternately stacked on top. However, either the first semiconductor layer 306 or the second semiconductor layer 308 may be the bottommost layer (or the layer most proximate from the semiconductor substrate 304), and either the first semiconductor layer 306 or the second semiconductor layer 308 may be the topmost layer (or the layer most distanced to the semiconductor substrate 304). The disclosure is not limited by the number of stacked semiconductor layers. A thickness (not labeled) of the respective first semiconductor layer 306 measured along the direction Z may be in a range of about 4 nm to about 12 nm. A thickness (not labeled) of the respective second semiconductor layer 308 measured along the direction Z may be in a range of about 6 nm to about 15 nm. Although other values of the thicknesses of the first and second semiconductor layers 306 and 308 are possible depending on product and process requirements.

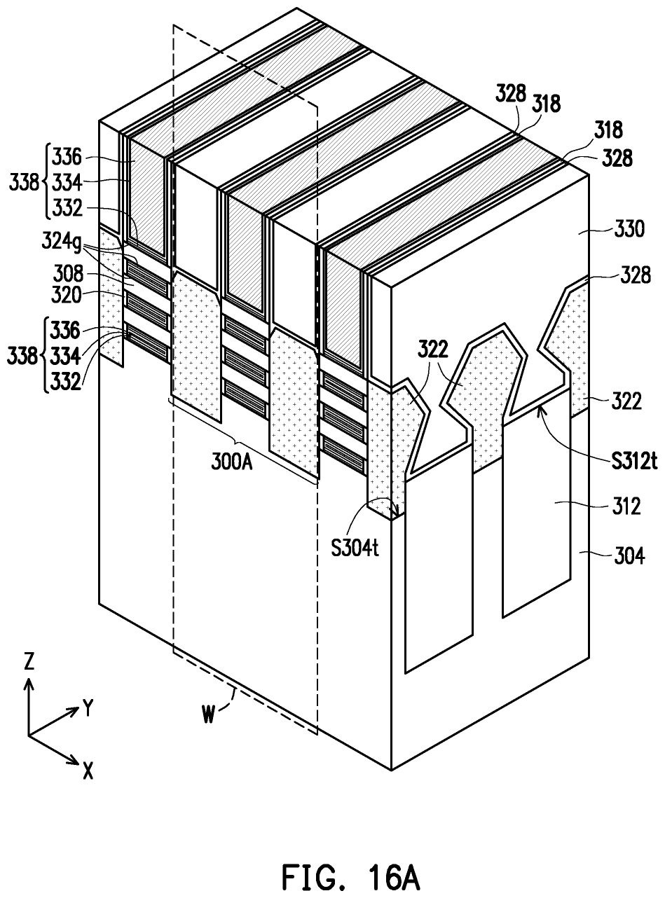

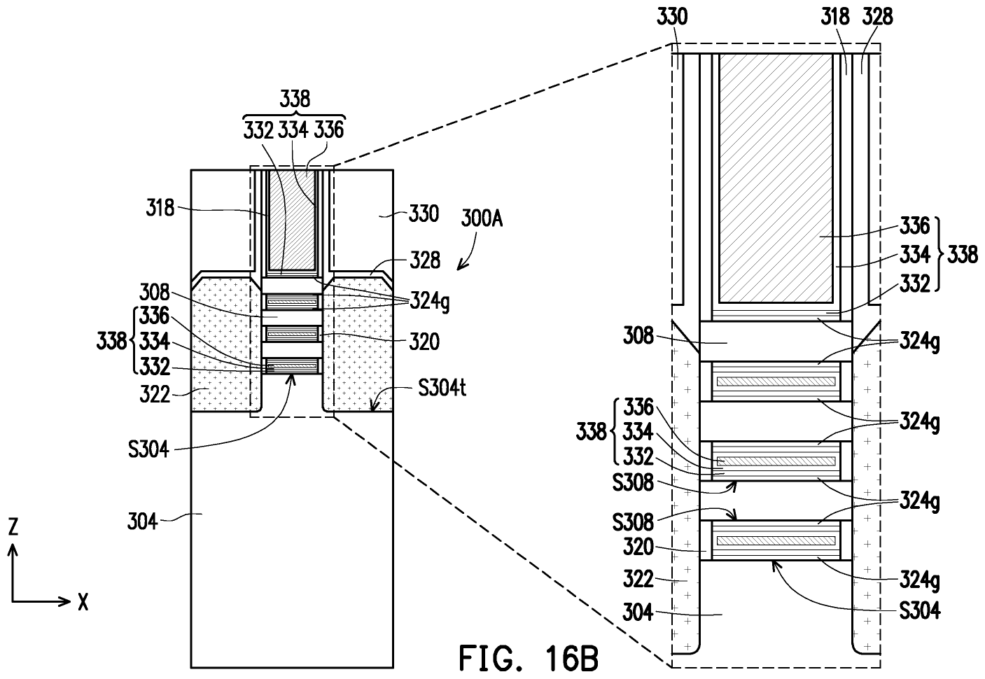

The first semiconductor layers 306 and the second semiconductor layers 308 may have different materials (or compositions) that may provide for different oxidation rates and/or different etch selectivity between the layers. For example, the second semiconductor layers 308 are formed of the same material as the semiconductor substrate 304, while the first semiconductor layers 306 may be formed of a different material which may be selectively removed with respect to the material of the semiconductor substrate 304 and the second semiconductor layers 308. In some embodiments, the material of the first semiconductor layers 306 includes silicon germanium (SiGe). For example, germanium (Ge) may include about 15% to 35% of the first semiconductor layers 306 of SiGe in molar ratio. In some embodiments, the second semiconductor layers 308 include silicon (Si), where each of the second semiconductor layers 308 may be undoped or substantially dopant-free. A method for forming the first and second semiconductor layers 306 and 308 may include epitaxial processes. The second semiconductor layers 308 may be considered as semiconductor channel layers or channel regions. That is, the second semiconductor layers 308 may be referred to as channels of a transistor 300A (in FIGS. 16A-16B and 17A-17B) of the semiconductor device SD1. However, the disclosure is not limited thereto, and other suitable material, or other combinations of materials for which selective etching is possible are contemplated within the scope of the disclosure.

Continued on FIG. 1, for example, a hard mask material 1002am and a hard mask material 1002bm are subsequently formed on the stacking structure (e.g., the stack of first and second semiconductor layers (306 and 308)). For example, the hard mask material 1002am is stacked on the stacking structure, and the hard mask material 1002bm is stacked on the hard mask material 1002am. The hard mask material 1002am and the hard mask material 1002bm are individually extended along a X-Y plane to cover up the stacking structure. The hard mask material 1002am and the hard mask material 1002bm may be made of different insulating materials. For instance, materials of the hard mask material 1002am and the hard mask material 1002bm may be selected from a group consisting of silicon oxide, silicon nitride, silicon oxynitride and the like. A method for forming the hard mask material 1002am and the hard mask material 1002bm may include one or more deposition processes, such as chemical vapor deposition (CVD) process or the like.

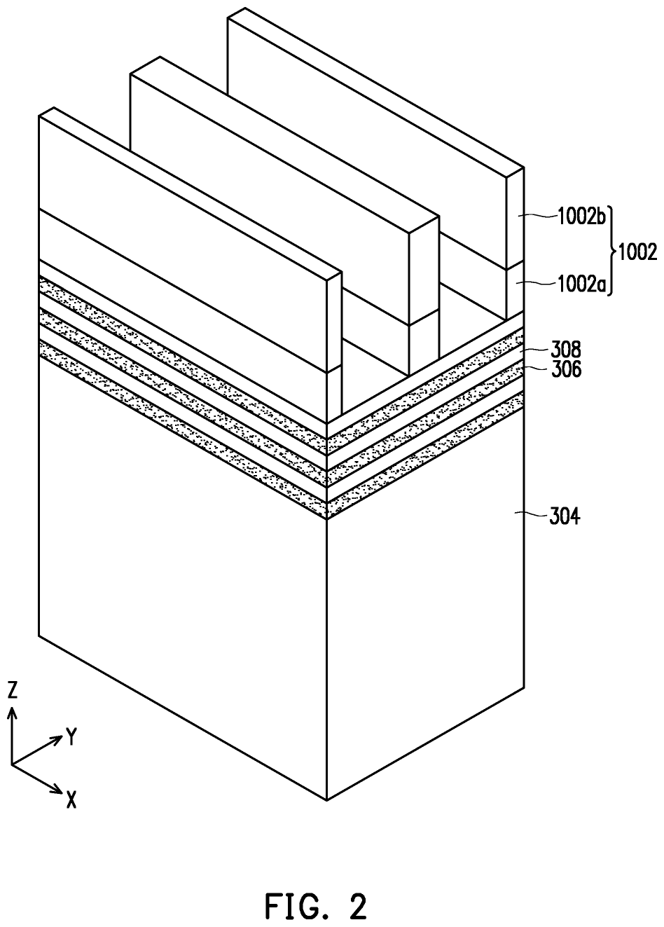

Referring to FIG. 2, in some embodiments, the hard mask material 1002am and the hard mask material 1002bm are patterned to form a plurality of hard mask structures 1002 over the stacking structure. In addition, in some embodiments, each hard mask structure 1002 includes a hard mask layer 1002a and a hard mask layer 1002b formed over the hard mask layer 1002a. In some embodiments, the hard mask structures 1002 are arranged along a direction Y, and are extending along a direction X. A method for forming of hard mask structures 1002 may include a self-aligned multiple patterning process (e.g., a self-aligned double patterning (SADP) process or a self-aligned quadruple patterning (SAQP) process). However, the disclosure is not limited thereto; alternatively, the hard mask structures 1002 each may be a single layer structure or include a structure having more than one sublayer by adjusting the number of hard mask materials formed over the stacking structure. The hard mask structures 1002 may be referred to as a hard mask, a hard mask pattern or a patterned mask structure, and the hard mask layers 1002a, 1002b may be referred to as mask strips or mask patterns.

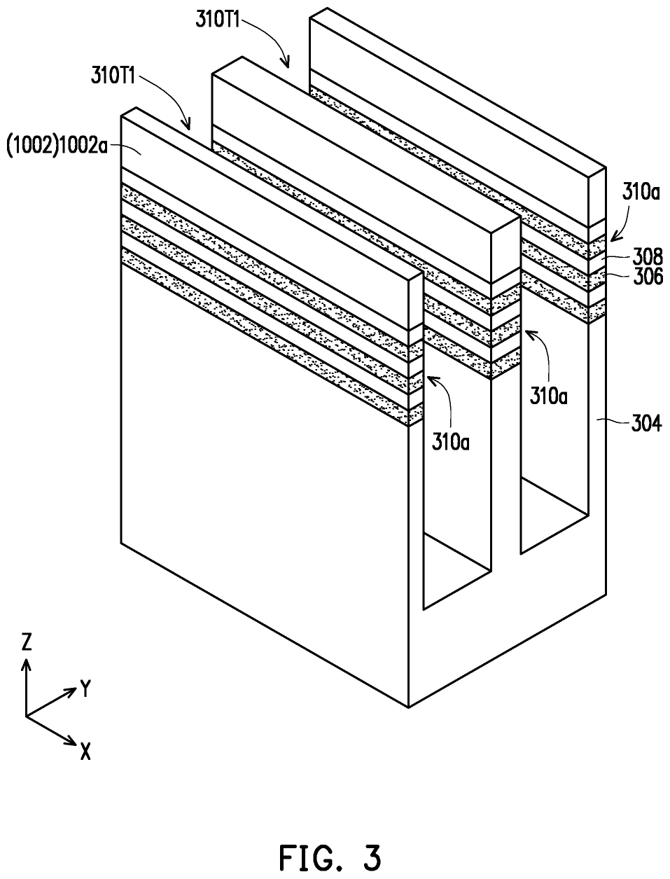

Referring to FIG. 2 and FIG. 3, in some embodiments, a portion of the stack of first and second semiconductor layers (306 and 308) and a portion of the semiconductor substrate 304 may be removed to form a plurality of first trenches (or openings) 310T1, thereby defining a fin structure 310a between two adjacent first trenches 310T1, in accordance with a step S102 of the method 100 in FIGS. 19A-19B. The first trenches 310T1 may arranged along the direction Y and continuously extend along the direction X. For example, the critical dimension (or the width as measured along the direction Y, not labeled) of the respective first trench 310T1 is in a range of about 25 nm to about 80 nm. The critical dimension (or the width as measured along the direction Y, not labeled) of the fin structures 310a may be in a range of about 5 nm to about 40 nm, depending on the N-type fin or the P-type fin. For example, the critical dimension of the N-type fin may be in a range of about 20 nm to about 40 nm, and the critical dimension of the P-type fin may be in a range of about 5 nm to about 20 nm. Although other values of the critical dimensions are possible depending on various device regions. It should be noted that the disclosure is not limited by the numbers of fin structures 310a depicted in FIG. 3, which may be adjusted according to the requirements of the circuit design. When multiple fin structures 310a are formed, the first trenches 310T1 may be disposed between any adjacent ones of the fin structures 310a.

The fin structures 310a may be formed by patterning portions of the stack of first and second semiconductor layers (306 and 308) and the semiconductor substrate 304. A method for patterning the stacking structure to form the fin structures 310a may include an etching process, such as an anisotropic etching process. The etching process may be stopped when a top portion of the semiconductor substrate 304 may be removed during the etching process as shown in FIG. 3, or be stopped when an illustrated top surface of the semiconductor substrate 304 may be exposed. For example, the hard mask structures 1002 are disposed over the topmost one of the second semiconductor layers 308 (also called the top semiconductor layer 308 herein). The hard mask structures 1002 are used as shadow masks to pattern exposed portions of the stack of first and second semiconductor layers (306 and 308) and the semiconductor substrate 304. In those embodiments where the hard mask structures 1002 are arranged along the direction Y and extending along the direction X, the formed fin structures 310a are also arranged along the direction Y and extending along the direction X. The fin structures 310a may be formed by etching trenches (e.g., the first trenches 310T1) in the stack of first and second semiconductor layers (306 and 308) and the semiconductor substrate 304. In some embodiments, the first trenches 310T1 may be parallel strips (when viewed from the top) elongated along the direction X and distributed along the direction Y. The fin structures 310a may be referred to a stacking structures extending along the direction X.

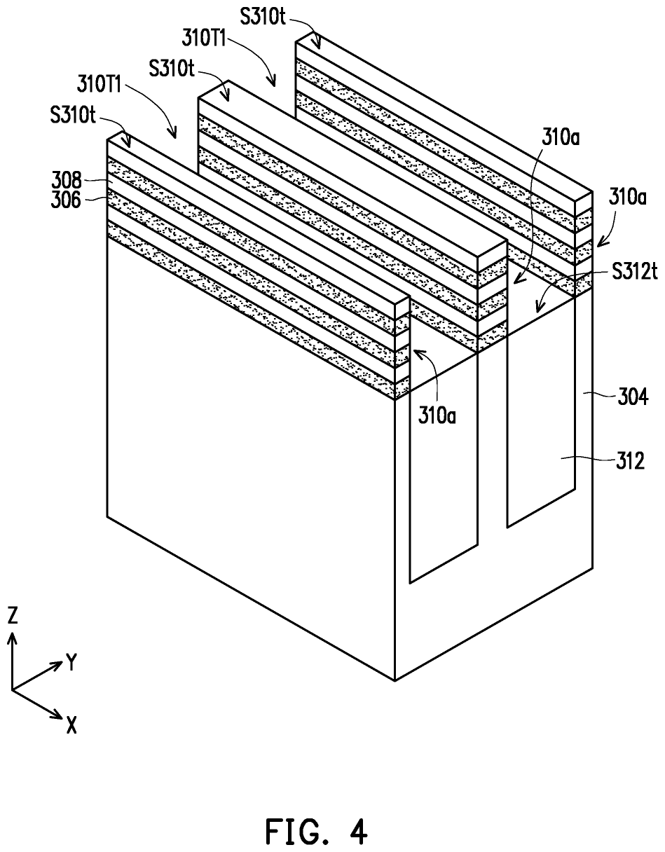

The hard mask structures 1002 may be optionally removed after forming the fin structures 310a. In some embodiments, the hard mask layers 1002b of the hard mask structures 1002 are removed during the etching process (as shown in FIG. 3), and the hard mask layers 1002a of the hard mask structures 1002 are then removed after forming the fin structures 310a (see FIG. 4) to expose surfaces S310t (e.g., illustrated top surfaces of topmost one of the second semiconductor layers 308) of the fin structures 310a. However, the disclosure is not limited thereto; alternatively, the hard mask structures 1002 may be removed during the subsequently-performed etching process.

Referring to FIG. 4, in some embodiments, a plurality of isolation structures 312 (sometimes referred to as shallow trench isolation (STI) structures) may be formed in lower portions of the first trenches 310T1, in accordance with a step S103 of the method 100 in FIGS. 19A-19B. For example, the isolation structures 312 extend at opposing sides of the semiconductor substrate 304 in the first trenches 310T1. In some embodiments where multiple fin structures 310a are provided, each of the isolation structures 312 is disposed between adjacent ones of the fin structures 310a and covers respectively a sidewall of a lower portion of the respective fin structure 310a. The isolation structures 312 may be formed of an insulation material (e.g., an oxide, a Si-based oxide (e.g., SiOC, SiOCN, or the like), a nitride, the like, any other suitable material, or combinations thereof) which may electrically isolate neighboring fin structures 310a from each other.

In some embodiments, the isolation structures 312 are formed by initially depositing a layer of insulation material (not shown) in the respective first trench 310T1 and recessing the layer of insulation material using an acceptable etching process, such as one that is selective to the material of the isolation structures 312. For example, a dry etching process is performed to form the isolation structures 312 having a relatively smooth top surfaces S312t. In alternative embodiments, a wet etching process is used. Or alternatively, a dry etching process and wet etching process are both used. The insulation material may be recessed to where illustrated top surfaces S312t of the isolation structures 312 are substantially coplanar to (e.g., substantially leveled with) the illustrated top surface (not labeled) of the semiconductor substrate 304, and the fin structures 310a protrude out of the illustrated top surface of the neighboring isolation structures 312. The illustrated top surfaces S312t of the isolation structures 312 may be a flat surface, a curved (e.g., convex or concave) surface, or combinations thereof, depending on the etching process. Alternatively, the insulation material may be recessed to where illustrated top surfaces S312t of the isolation structures 312 are below the illustrated top surface of the semiconductor substrate 304, and the fin structures 310a protrude out of the illustrated top surface of the neighboring isolation structures 312.

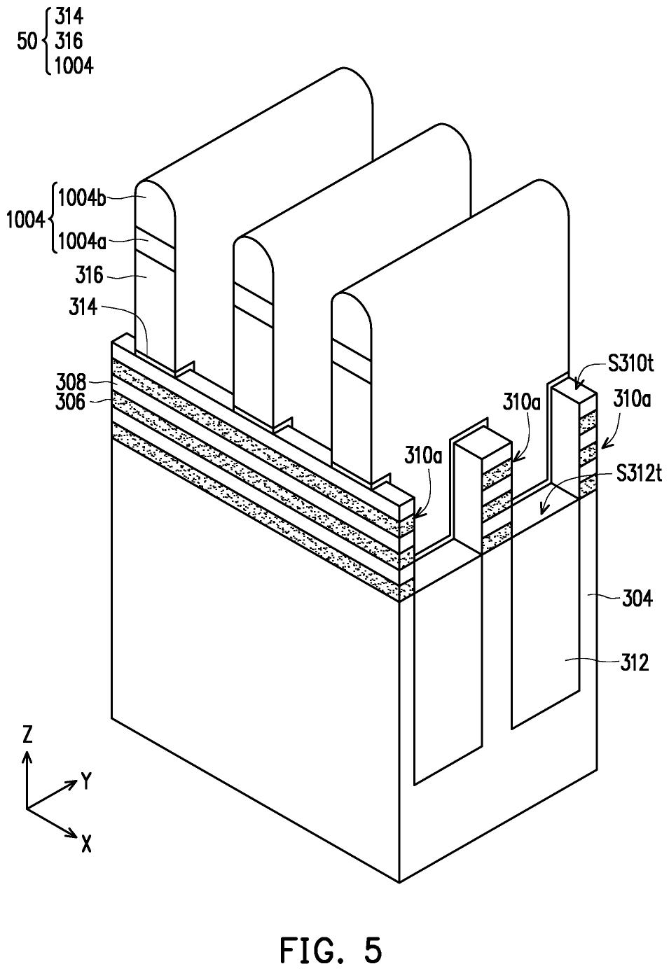

Referring to FIG. 5, in some embodiments, sacrificial gate structures 50 are formed on the semiconductor substrate 304, in accordance with a step S104 of the method 100 in FIGS. 19A-19B. An extending direction of the sacrificial gate structures 50 is intersected with an extending direction of the fin structures 310a, and the sacrificial gate structures 50 cover portions of the fin structures 310a that are overlapped with the sacrificial gate structures 50. In those embodiments where the fin structures 310a are arranged along the direction Y and extending along the direction X, the sacrificial gate structures 50 may be arranged along the direction X and extend along the direction Y. The sacrificial gate structures 50 may be referred to as dummy gate structures. In some embodiments, each sacrificial gate structure 50 includes a dummy gate dielectric layer 314 and a dummy gate electrode 316. The dummy gate dielectric layer 314 is conformally formed on the semiconductor substrate 304 and the fin structures 310a, whereas the dummy gate electrode 316 covers the dummy gate dielectric layer 314, and are formed to a height greater than a height of the fin structures 310a. In some embodiments, each sacrificial gate structure 50 further includes a capping structure 1004 lying on the dummy gate electrode 316. The capping structure 1004 may include a capping layer 1004a and a capping layer 1004b lying above the capping layer 1004a. In some embodiments, the capping layer 1004b has rounded top corners.

Materials of the dummy gate dielectric layer 314, the capping layer 1004a and the capping layer 1004b may respectively include silicon oxide, silicon nitride, silicon oxynitride, the like or combinations thereof, whereas a material of the dummy gate electrode 316 may include polysilicon. In addition, methods for forming the dummy gate dielectric layer 314, the capping layers 1004a, 1004b and the dummy gate electrode 316 may respectively include a deposition process, such as a CVD process or an atomic layer deposition (ALD) process. In each sacrificial gate structure 50, the dummy gate dielectric layer 314 may be referred to as a dummy gate dielectric strip, a sacrificial gate dielectric layer or a sacrificial gate dielectric strip, the dummy gate electrode 316 may be referred to as dummy gate electrode strip 316, a sacrificial gate electrode 316 or a sacrificial gate electrode strip 316, the capping structure 1004 may be referred to as a hard mask, a hard mask pattern or a patterned mask structure, and the capping layers 1004a, 1004b may be referred to as mask strips or mask patterns.

Referring to FIG. 6A and FIG. 6B, in some embodiments, a gate spacer layer 318m is formed on the structure depicted in FIG. 5. In some embodiments, the gate spacer layer 318m is globally formed over the structure as shown in FIG. 5. In these embodiments, the semiconductor substrate 304, the fin structures 310a and the sacrificial gate structures 50 (including the dummy gate dielectric layer 314, the dummy gate electrode 316, and the capping structure 1004) may be entirely covered by the gate spacer layer 318m. A material of the gate spacer layer 318m may include silicon oxide, silicon nitride, silicon carbide, silicon oxynitride (SiON), silicon carbide nitride (SiCN), silicon oxycarbide (SiOC), silicon carbide oxynitride (SiOCN), the like or combinations thereof, and a method for forming the gate spacer layer 318m may include a deposition process, such as a CVD process or an ALD process.

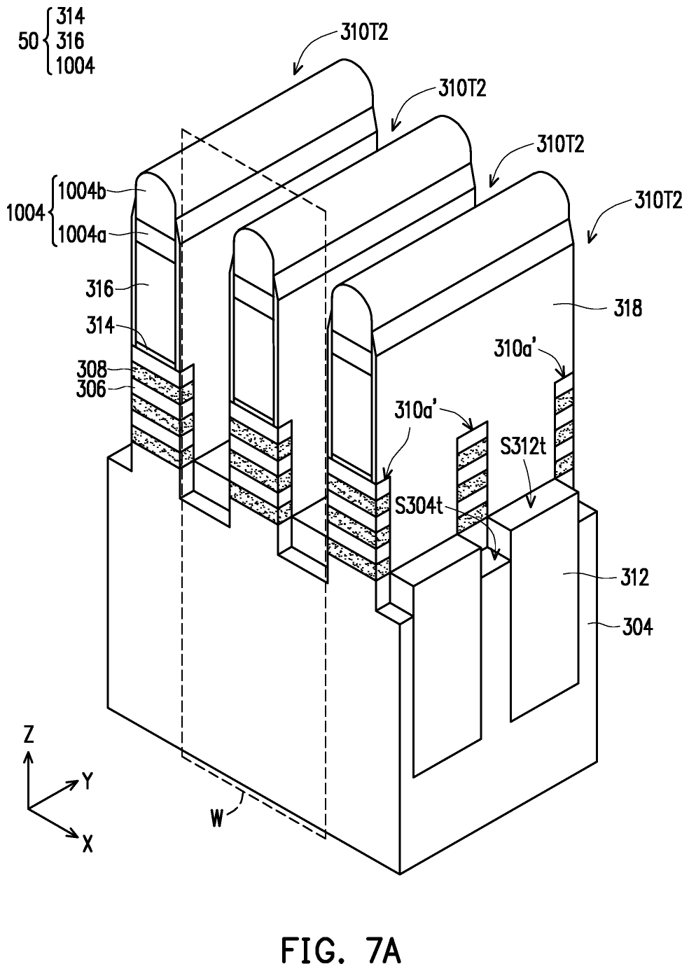

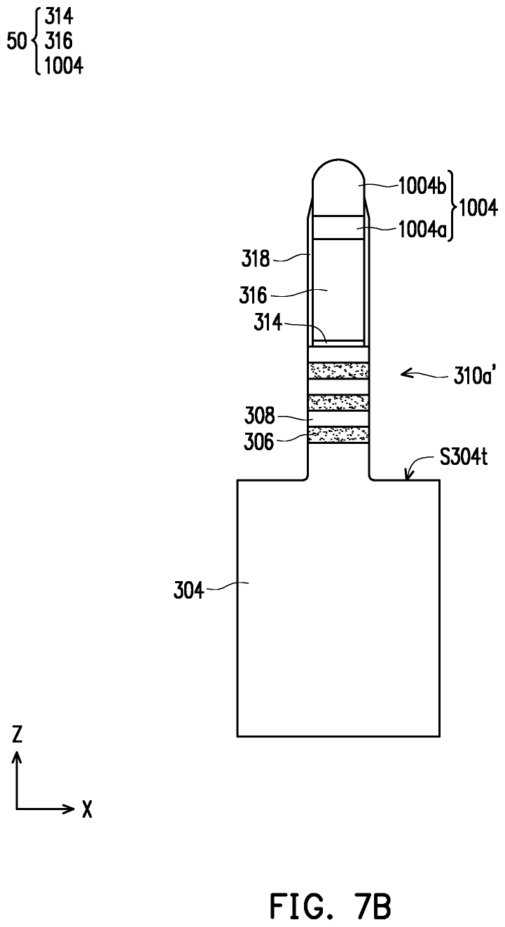

Referring to FIG. 7A and FIG. 7B, in some embodiments, some portions of the fin structures 310a and the gate spacer layer 318m are removed to form a plurality of second trenches (or openings) 310T2, thereby forming fin structure 310a′ and gate spacers 318. As shown in FIG. 7A, one sacrificial gate structure 50 and a respective underlying one fin structure 310a′ are located between two adjacent second trenches 310T2, for example. The second trenches 310T2 may arranged along the direction X and continuously extend along the direction Y. For example, the critical dimension (or the width measured along the direction X, not labeled) of the respective second trench 310T2 is in a range of about 25 nm to about 80 nm. The critical dimension (or the width measured along the direction X, not labeled) of the fin structures 310a′ may be in a range of about 5 nm to about 40 nm, depending on the N-type fin or the P-type fin. For example, the critical dimension of the N-type fin may be in a range of about 20 nm to about 40 nm, and the critical dimension of the P-type fin may be in a range of about 5 nm to about 20 nm. Although other values of the critical dimensions are possible depending on various device regions. It should be noted that the disclosure is not limited by the numbers of fin structures 310a′ depicted in FIG. 7A, which may be adjusted according to the requirements of the circuit design. When multiple fin structures 310a′ are formed, the second trenches 310T2 may be disposed between any adjacent ones of the fin structures 310a′. In some embodiments, the first trenches 310T1 and the second trenches 310T2 are spatially communicated to each other.

In some embodiments, portions of the gate spacer layer 318m covering the sidewalls of the sacrificial gate structures 50 are remained, and the rest of the gate spacer layer 318m are removed, so to form the gate spacers 318. On the other hand, portions of the fin structures 310a not covered by the sacrificial gate structures 50 and the gate spacers 318 are accordingly exposed. Thereafter, the exposed portions of the fin structures 310a are removed, whereas portions of the fin structures 310a covered by the gate spacers 318 and the sacrificial gate structures 50 are remained to form the fin structure 310a′. For example, the sacrificial gate structures 50 and the gate spacers 318 together are used as shadow masks to pattern the exposed portions of the fin structures 310a. In some embodiments, a method for removing these portions of the fin structures 310a and the gate spacer layer 318m may include one or more etching processes, such as one or more anisotropic etching processes.

The etching process may be stopped when a top portion of the semiconductor substrate 304 may be removed during the etching process(es) as shown in FIG. 7A and FIG. 7B, where illustrated top surfaces S304t of the semiconductor substrate 304 exposed by the second trenches 310T2 is lower than illustrated top surfaces of the semiconductor substrate 304 within the fin structures 310a′. In the case, the isolation structures 312 are not removed during the etching process(es), where illustrated top surface S312t of the isolation structures 312 are above the illustrated top surface S304t of the semiconductor substrate 304 exposed by the second trenches 310T2. The isolation structures 312 each may include a planar top surface. In such case, as shown in FIG. 7A, the illustrated top surfaces of the semiconductor substrate 304 within the fin structures 310a′ may be substantially leveled with (e.g., substantially coplanar to) the illustrated top surface S312t of the isolation structures 312, within process variations.

The disclosure is not limited thereto. Alternatively, the etching process may be stopped at the illustrated top surfaces of the semiconductor substrate 304 exposed by the second trenches 310T2 without removing semiconductor substrate 304. For example, the portions of the semiconductor substrate 304 overlapping with the second trenches 310T2 and the portions of the semiconductor substrate 304 overlapping with the fin structures 310a′ have illustrated top surfaces being be substantially leveled with (e.g., substantially coplanar to) one another. In such case, the illustrated top surfaces of the semiconductor substrate 304 (e.g., the portions overlapping with the second trenches 310T2 and the portions overlapping with the fin structures 310a′) may be substantially leveled with (e.g., substantially coplanar to) the illustrated top surfaces S312t of the isolation structure 312, within process variations. As shown in FIG. 7A and FIG. 7B, in some embodiments, the sacrificial gate structures 50 and the gate spacers 318 entirely stand on the fin structures 310a′. In other words, a projection of one sacrificial gate structure 50 and a projection of a respective pair of the gate spacers 318 disposed at two opposite sides of the sacrificial gate structure 50 may be completely inside a projection of a respective one of the fin structures 310a′ along the direction Z.

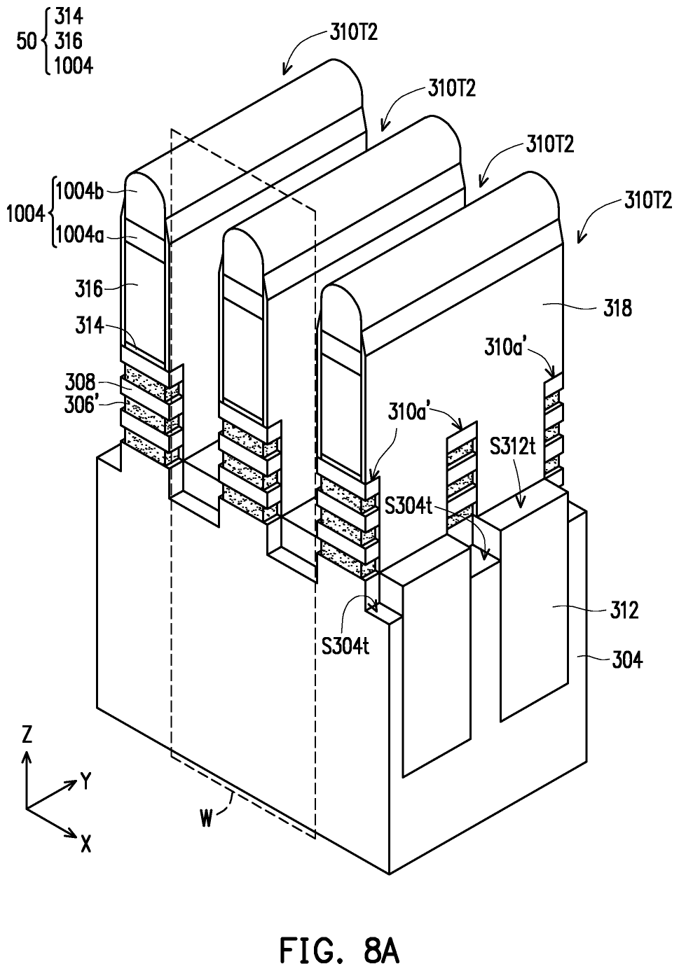

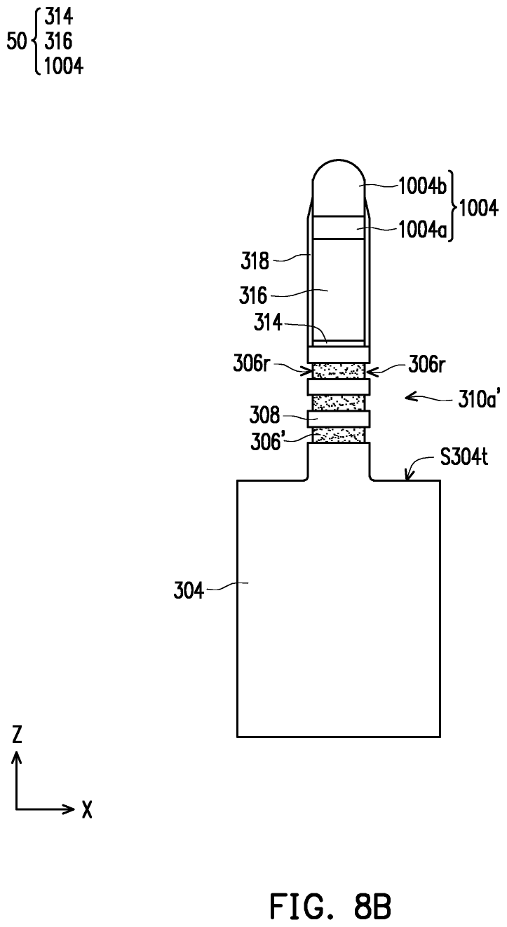

Referring to FIG. 8A and FIG. 8B, in some embodiments, the first semiconductor layers 306 are laterally recessed from the second semiconductor layers 308 and the gate spacers 318 to form first semiconductor layers 306′ and a plurality of recesses 306r at opposite sides of each of the first semiconductor layers 306′. In the case, the recesses 306r are formed at sidewalls of the remained portions of the fin structures 310a′. In some embodiments, the first semiconductor layers 306 are laterally recessed from the second semiconductor layers 308 and the gate spacers 318 by a distance ranging from about 0.5 nm to about 1 nm. A method for lateral recessing the first semiconductor layers 306 may include an etching process, such as an isotropic etching process. By properly selecting etchants for the etching process and/or by properly selecting the materials of the first semiconductor layers 306 and the second semiconductor layers 308, the first semiconductor layers 306 can be etched without consuming the second semiconductor layers 308 and other components in the current structure. In some embodiments, the recesses 306r, the first trenches 310T1 and the second trenches 310T2 are spatially communicated to each other. The recesses 306r may be referred to as lateral recesses.

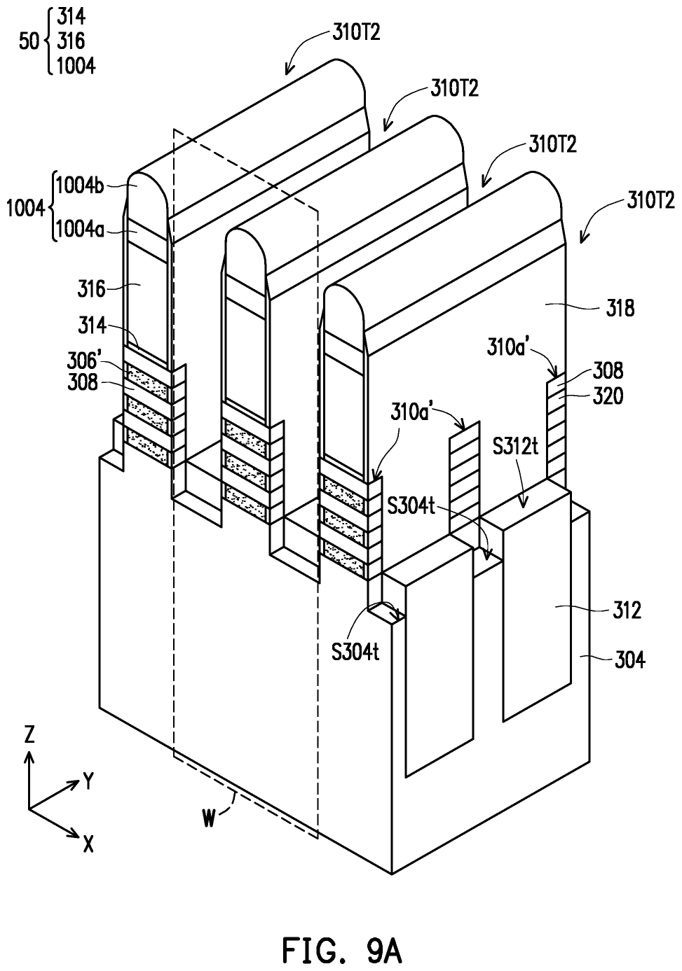

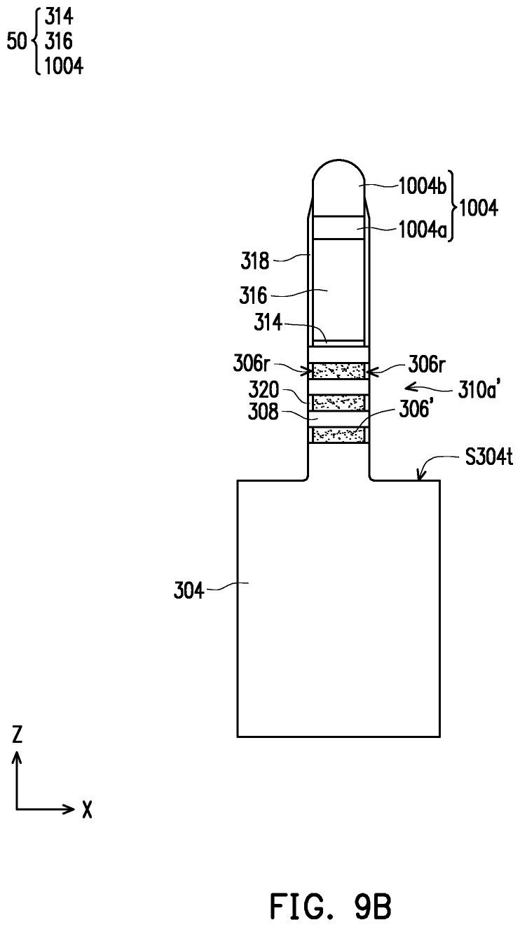

Referring to FIG. 9A and FIG. 9B, in some embodiments, a plurality of inner spacers 320 are formed in the recesses 306r by filling an insulating material in the recesses 306r at the sidewalls of the fin structures 310a′. In some embodiments, exposed sidewalls of the inner spacers 320 are substantially coplanar with sidewalls of the second semiconductor layers 308 and sidewalls of the gate spacers 318. In alternative embodiments, the exposed sidewalls of the inner spacers 320 are dented from the sidewalls of the second semiconductor layers 308 and the sidewalls of the gate spacers 318. A material of the insulating material for forming the inner spacers 320 may include silicon oxide, silicon nitride, silicon carbide, silicon carbide nitride, silicon oxide carbide, silicon carbide oxynitride, or other suitable dielectric materials or combinations thereof. A method for forming the inner spacers 320 may include initially forming a material layer globally covering the structure shown in FIG. 8A and FIG. 8B, and then removing portions of this blanket layer outside the recesses 306r. In this way, the remained portions of this material layer form the inner spacers 320. In some embodiments, the material layer is formed by using a deposition process (e.g., a CVD process or an ALD process), and the portions of the material layer are removed by using an etching process (e.g., an anisotropic etching process). The inner spacers 320 may be formed from the same or different material as the gate spacers 318.

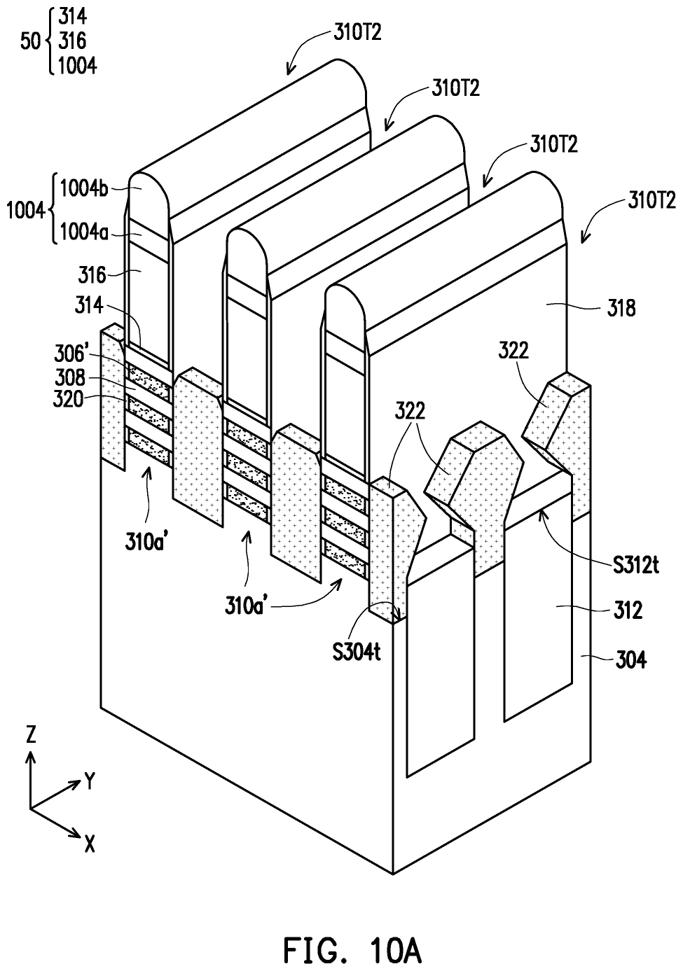

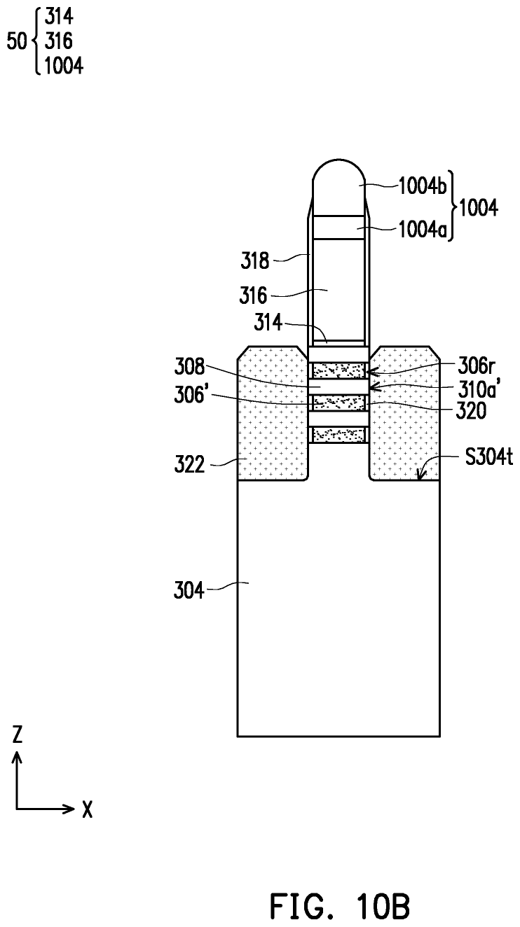

Referring to FIG. 10A and FIG. 10B, in some embodiments, a plurality of source/drain regions 322 are formed over the semiconductor substrate 304 within the second trenches 310T2 between the fin structures 310a′, in accordance with a step S105 of the method 100 in FIGS. 19A-19B. In some embodiments, one source/drain region 322 is disposed between two adjacent isolation structures 312 arranged along the direction Y. On the other hand, each of the fin structures 310a′ is disposed between two adjacent source/drain regions 322 along the direction X. For example, as shown in FIG. 10A and FIG. 10B, the source/drain regions 322 are disposed on (e.g., in physical contact with) the illustrated top surfaces S304t of the semiconductor substrate 304 exposed by the second trenches 310T2 and further protrudes out of the illustrated top surfaces S312t of the isolation structures 312 and the illustrated top surface (not labeled)) of the semiconductor substrate 304 underlying the fin structures 310a′. In some embodiments, illustrated top surfaces (not labeled) of the source/drain regions 322 is at a plane substantially coplanar to (e.g., leveled with) the illustrated top surfaces S310t of the fin structures 310a′. Alternatively, the illustrated top surfaces of the source/drain regions 322 may be above the illustrated top surfaces S310t of the fin structures 310a′. Or alternatively, the illustrated top surfaces of the source/drain regions 322 may be below the illustrated top surfaces S310t of the fin structures 310a′.

The source/drain regions 322 may each include silicon germanium, indium arsenide, indium gallium arsenide, indium antimonide, germanium arsenide, germanium antimonide, indium aluminum phosphide, indium phosphide, any other suitable material, or combinations thereof. The source/drain regions 322 may be formed using an epitaxial layer growth process on the exposed surfaces of each of the second semiconductor layers 308 and the inner spacers 320. The material of the source/drain regions 322 may be doped with a conductive dopant. For example, a strained material is epitaxial grown with an n-type dopant (or a p-type dopant) for straining the source/drain regions 322 in the n-type region (or the p-type region). That is, the strained material is doped with the n-type dopant (or the p-type dopant) to be the source/drain regions 322 of the p-type FET (or the n-type FET). For one non-limiting example, the source/drain regions 322 include SiGe, which are epitaxial-grown with a p-type dopant for straining a p-type FET. In the case, the p-type dopant includes boron or BF₂, and the source/drain regions 322 are epitaxial-grown by LPCVD process with in-situ doping. For another non-limiting example, the source/drain regions 322 include SiC, which are epitaxial-grown with an n-type dopant for straining an n-type FET. In the case, the n-type dopant includes arsenic and/or phosphorus, and the source/drain regions 322 are epitaxial-grown by LPCVD process with in-situ doping.

In some embodiments, the source/drain regions 322 are grown to have substantially identical size. The source/drain regions 322 may be symmetrical to one another, as shown in FIG. 10A and FIG. 10B. The disclosure is not limited thereto; alternatively, the source/drain regions 322 may be grown to have different sizes. In some embodiments, the source/drain regions 322 located at the same side of the fin structures 310a′ along the direction X and arranged along the direction Y may be grown to physically spacing away from each other, which may be considered as discrete pieces, as shown in FIG. 10A and FIG. 10B. Alternatively, the source/drain regions 322 located at the same side of the fin structures 310a′ along the direction X and arranged along the direction Y may be grown to physically connected to each other, which may be together considered as an integral piece. The source/drain regions 322 may be coupled to the exposed surfaces of the second semiconductor layers 308 of the fin structures 310a′ (along the Y-direction) and the inner spacers 320.

As shown in FIG. 10A and FIG. 10B, the source/drain regions 322 may be disposed as a single-layered structure. The disclosure is not limited thereto; alternatively, the source/drain regions 322 may be disposed as a multi-layered structure, with different layers having different degrees of doping. In some embodiments, as shown in FIG. 10A and FIG. 10B, the illustrated top surfaces of the source/drain regions 322 is above the illustrated top surfaces S312t of the isolation structures 312. It should be noted that the source/drain regions 322 may have other types of configurations, while remaining within the scope of the disclosure. The source/drain regions 322 may be referred to as epitaxial structures, epitaxial layers (epi layers), strained elements, or strained structures. The source/drain regions 322 may be referred to as source/drain structures or source/drain features of the transistor 300A of the semiconductor device SD1.

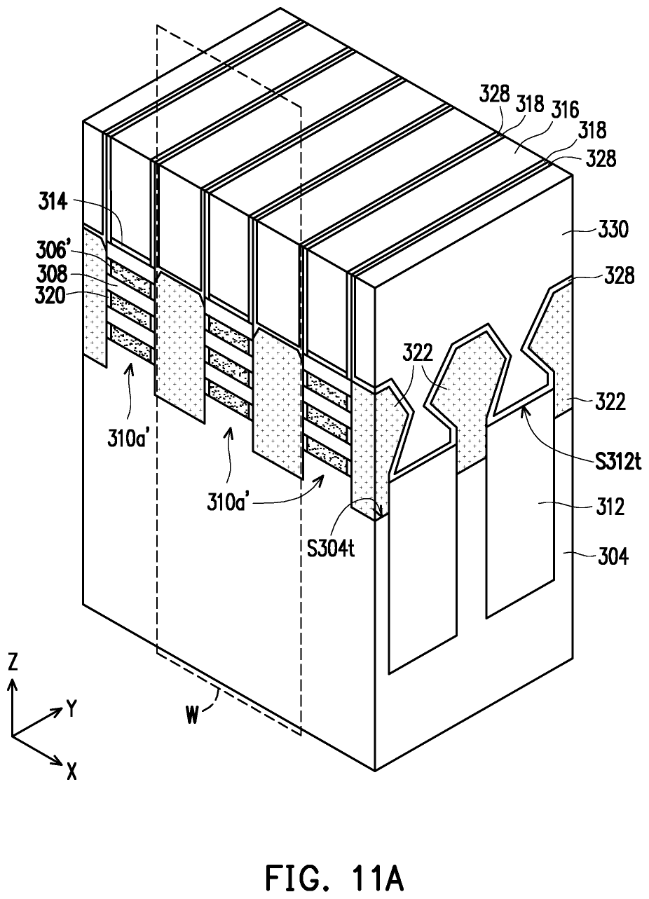

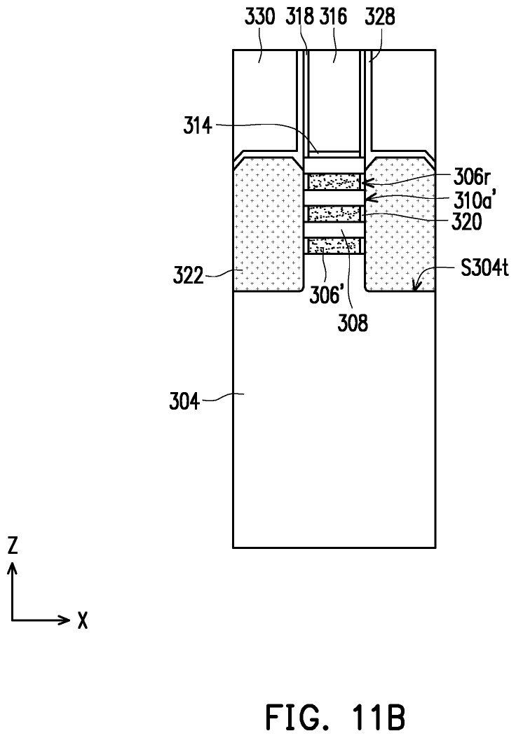

Referring to FIG. 11A and FIG. 11B, in some embodiments, a dielectric layer 328 is globally formed on the structure depicted in FIG. 10A and FIG. 10B. The dielectric layer 328 may be completely disposed on the source/drain regions 322, the sacrificial gate structures 50, the gate spacers 318, and the isolation structures 312 exposed therefrom, as shown in FIG. 11A and FIG. 11B. The dielectric layer 328 includes, for example, a suitable material such as silicon nitride, silicon oxynitride, silicon nitride with oxygen or carbon elements, the like or combinations thereof. In some embodiments, the dielectric layer 328 is deposited by using processes such as CVD (e.g., high density plasma (HDP) CVD or sub-atmospheric CVD (SACVD)), ALD, molecular layer deposition (MLD), or other suitable methods. The dielectric layer 328 functions as a protection layer that effectively blocks water or moisture from penetrating into the elements underlying thereto or damages from the subsequent process(es) such as an etching process. The dielectric layer 328 may be referred to as a protection layer, an etch stop layer or a contact etch stop (CES) layer. A thickness of the dielectric layer 328 measured along the direction Z may be in a range of about 1 nm to about 8 nm. Although other value of the thickness of the dielectric layer 328 is possible depending on product and process requirements.

Thereafter, an interlayer dielectric (ILD) layer 330 is formed over the dielectric layer 328, in some embodiments, in accordance with a step S106 of the method 100 in FIGS. 19A-19B. For example, the ILD layer 330 is disposed at opposing sides (along the Y-direction) of each sacrificial gate structures 50 to overlay the source/drain regions 322 and the isolation structures 312, with the dielectric layer 328 disposed therebetween. The ILD layer 330 may be formed of a dielectric material such as silicon oxide, silicon oxide, silicon nitride, silicon oxynitride, silicon carbonitride, silicon carbide oxynitride, spin-on glass (SOG), tetraethylorthosilicate (TEOS) oxide, phosphosilicate glass (PSG), borosilicate glass (BSG), boron-doped phosphosilicate Glass (BPSG), fluoride-doped silicate glass (FSG), undoped silicate glass (USG), carbon doped silicon oxide (e.g., SiCOH), polyimide, and/or a combination thereof. In some alternative embodiments, the ILD layer 330 may include low-K dielectric materials. It should be noted that the low-k dielectric materials are generally dielectric materials having a dielectric constant lower than 3.9. Examples of low-K dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. It is understood that the ILD layer 330 may include one or more dielectric materials. In some embodiments, the ILD layer 330 is formed to a suitable thickness by CVD (such as flowable chemical vapor deposition (FCVD), HDP CVD, and SACVD), spin-on, sputtering, or other suitable methods. The ILD layer 330 may be referred to as an isolation dielectric structure or a dielectric structure.

In some embodiments, a material layer of the dielectric layer 328 may be conformally formed over the source/drain regions 322 and the isolation structures 312, the sacrificial gate structures 50, and the gate spacers 318. Next, a material layer of the ILD layer 330 may be formed over the dielectric layer 328 and fills the second trenches 310T2. Subsequently, a planarization process (e.g., a grinding process, a chemical mechanical polishing (CMP) process, an etching process, or combinations thereof) may be performed to remove excess materials of the dielectric layer 328 and the ILD layer 330. In some embodiments, the planarization process may also remove the capping structures 1004 to expose illustrated top surfaces of the dummy gate electrodes 316 of the sacrificial gate structures 50. After the planarization process, illustrated top surfaces of the ILD layer 330 and the dielectric layer 328 may be substantially leveled with (e.g., coplanar to) illustrated top surfaces of remaining portions of the sacrificial gate structures 50 (e.g., the illustrated top surfaces of the dummy gate electrodes 316) and illustrated top surfaces of the gate spacers 318, within process variations.

In certain cases, parts of top portions of the dummy gate electrodes 316 of the sacrificial gate structures 50 may also be removed during the planarization process. After the planarization process, a cleaning step may be optionally performed, for example to clean and remove the residue generated from the planarization process.

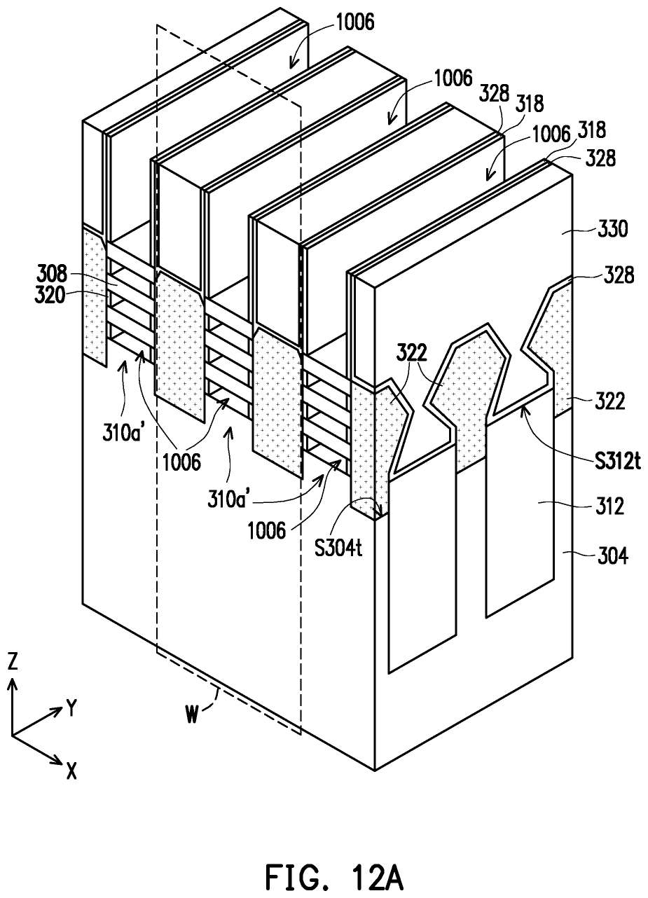

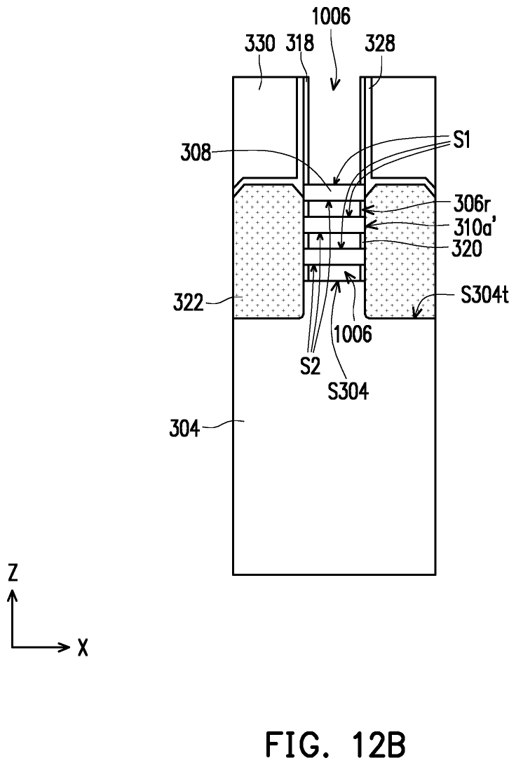

Referring to FIG. 12A and FIG. 12B, in some embodiments, the sacrificial gate structures 50 are removed from the structure depicted in FIG. 11A and FIG. 11B, in accordance with a step S107 of the method 100 in FIGS. 19A-19B. For example, after the dummy gate electrodes 316 of the sacrificial gate structures 50 are accessibly revealed, the dummy gate electrodes 316 and the dummy gate dielectric layers 314 of the sacrificial gate structures 50 are removed to form a plurality of first recesses each disposing between a respective pair of the gate spacers 318. Thereafter, the first semiconductor layers 306′ are also removed to respectively form a plurality of second recesses each disposing between a respective pair of the inner spacers 320, so to release the second semiconductor layers 308, in accordance with a step S108 of the method 100 in FIGS. 19A-19B. In addition, after removing the first semiconductor layers 306′, surface S304 of the semiconductor substrate 304 within the fin structures 310a′ are also accessibly revealed by the cavities 1006. The removal process may include an etching process (such as a dry etching, a wet etching, or a combination thereof) or any other suitable process. In some embodiments, a method for removing the first semiconductor layers 306′ may include an isotropic etching process. By properly selecting etchants for the etching process and/or properly selecting the materials of the first semiconductor layers 306′ and the second semiconductor layers 308, the first semiconductor layers 306′ can be etched without removing the second semiconductor layers 308 and other components in the current structure. In the case, the isotropic etching process is a selective etching process removing the first semiconductor layers 306′, while leaving the second semiconductor layers 308 and other components (e.g., the semiconductor substrate 304, the ILD layer 330, the dielectric layer 328, the gate spacers 318, the inner spacers 320, and so on) in the current structure substantially intact. During the removal process, the ILD layer 330 and the dielectric layer 328 may protect the source/drain regions 322 and the isolation structures 312. In some embodiments the first recesses and the second recesses are spatially communicated to each other to form cavities 1006. That is, the channel regions of the transistor 300A are released. Surfaces S308 of the second semiconductor layers 308 may be exposed (e.g., accessibly revealed) by the cavities 1006, as shown in FIGS. 12A and 12B. In addition, inner sidewalls of the inner spacers 320 and the exposed surface S304 of the semiconductor substrate 304 previously covered by the first semiconductor layers 306′ are currently exposed in the cavities 1006, as well.

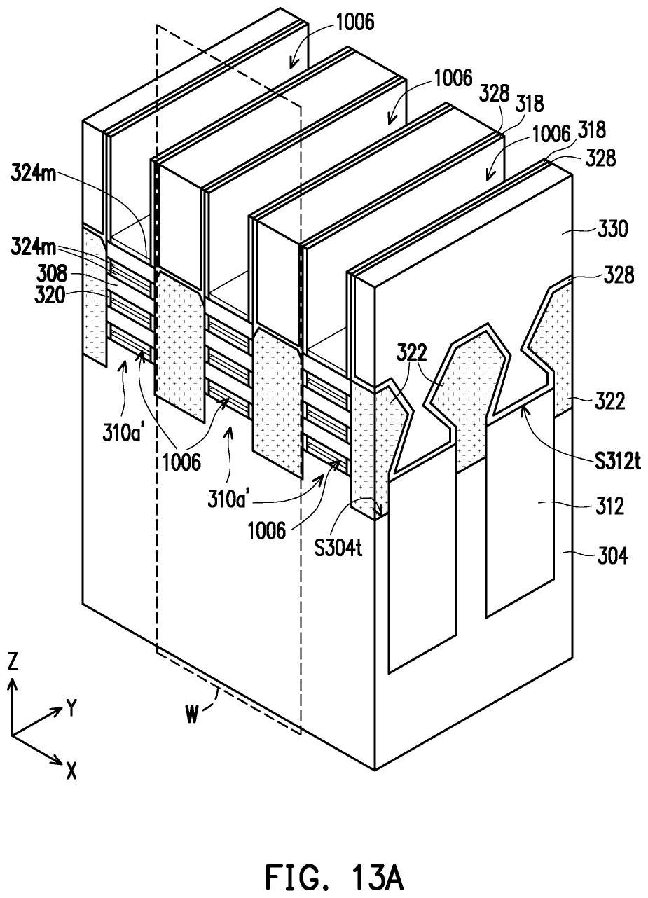

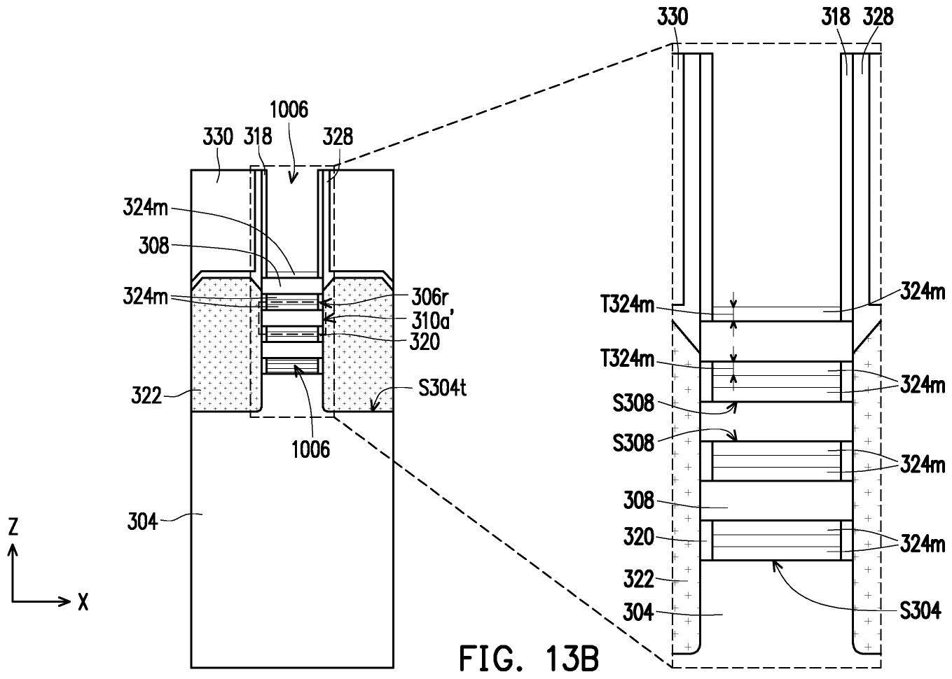

Referring to FIG. 13A and FIG. 13B, in some embodiments, a semiconductor material 324m is disposed on the exposed surfaces S308 of the second semiconductor layers 308 and the exposed surfaces S304 of the semiconductor substrate 304, in accordance with a step S110 of the method 100 in FIGS. 19A-19B. For example, the semiconductor material 324m are formed in the cavies 1006 to completely cover the second semiconductor layers 308 and the semiconductor substrate 304. That is, the semiconductor material 324m formed in the cavies 1006 to completely clad (e.g., entirely wrap) the exposed surfaces S308 of the second semiconductor layers 308 and the exposed surfaces S304 of the semiconductor substrate 304. In some embodiments, a material of the semiconductor material 324m is made of Si_{1-w}Ge_{w}, where w is less than or substantially equal to 0.5, such as w is in a range of about 0.1 to about 0.5. In a non-limiting example, the semiconductor material 324m is a crystal SiGe (c-SiGe) layer, with a composition of Si_{1-w}Ge_{w}, where w is less than or substantially equal to 0.5, such as w is in a range of about 0.15 to about 0.3. In another non-limiting example, the semiconductor material 324m is a c-SiGe layer, with a composition of Si_{1-w}Ge_{w}, where w is less than or substantially equal to 0.5, such as w is in a range of about 0.2 to about 0.3. The semiconductor material 324m may be a single c-SiGe layer. Alternatively, the semiconductor material 324m may be a strained single c-SiGe layer.

In some embodiments of which the transistor 300A is a GAA transistor or a nanowire transistor, a thickness T324m (as measured along the direction Z) of the semiconductor material 324m is in a range of about 3 nm to about 5 nm. Although other values of the thickness of the semiconductor material 324m are possible depending on product and process requirements. In other alternative embodiments of which the transistor 300A is a planar FET transistor or a TFET transistor, a thickness (as measured along a stacking direction of such semiconductor material layer and a respective channel region) of the semiconductor material layer is in a range of about 3 nm to about 30 nm. In further alternative embodiments of which the transistor 300A is a finFET transistor, a thickness (as measured along a stacking direction of such semiconductor material layer and a respective channel region) of the semiconductor material layer is in a range of about 3 nm to about 15 nm. In some embodiments, a method for forming the semiconductor material 324m includes a selectivity epitaxy by a deposition process (such as a CVD process or the like) so that the semiconductor material 324m is only formed on the second semiconductor layers 308 and the semiconductor substrate 304 exposed by the cavities 1006. The semiconductor material 324m may be referred to as an epi layer or a strained material layer. Although other forming methods of the semiconductor material 324m are possible depending on product and process requirements. As shown in FIG. 13A and FIG. 13B, the semiconductor material 324m is conformally disposed on the second semiconductor layers 308 and the semiconductor substrate 304 exposed by the cavities 1006, for example.

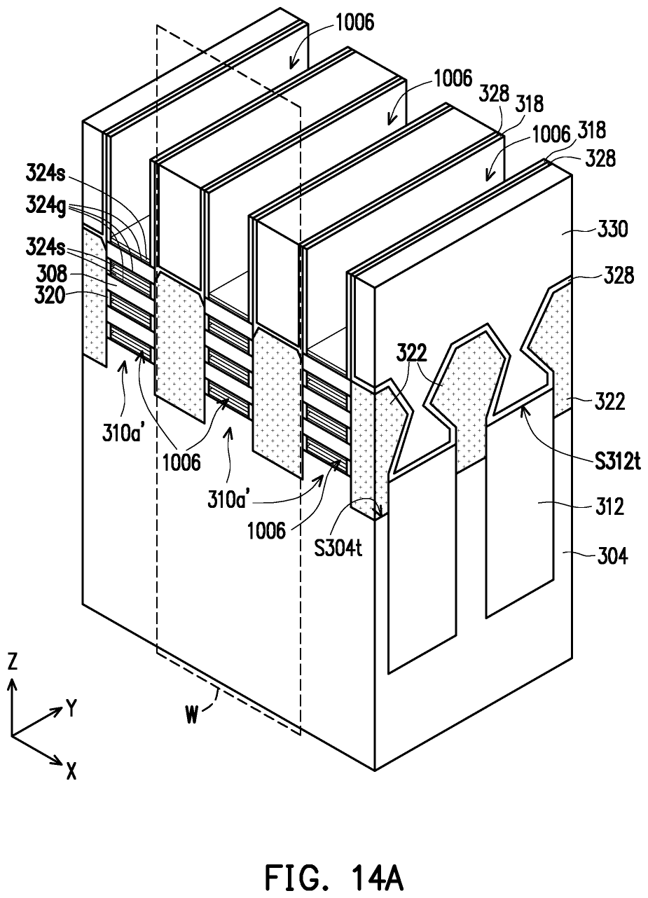

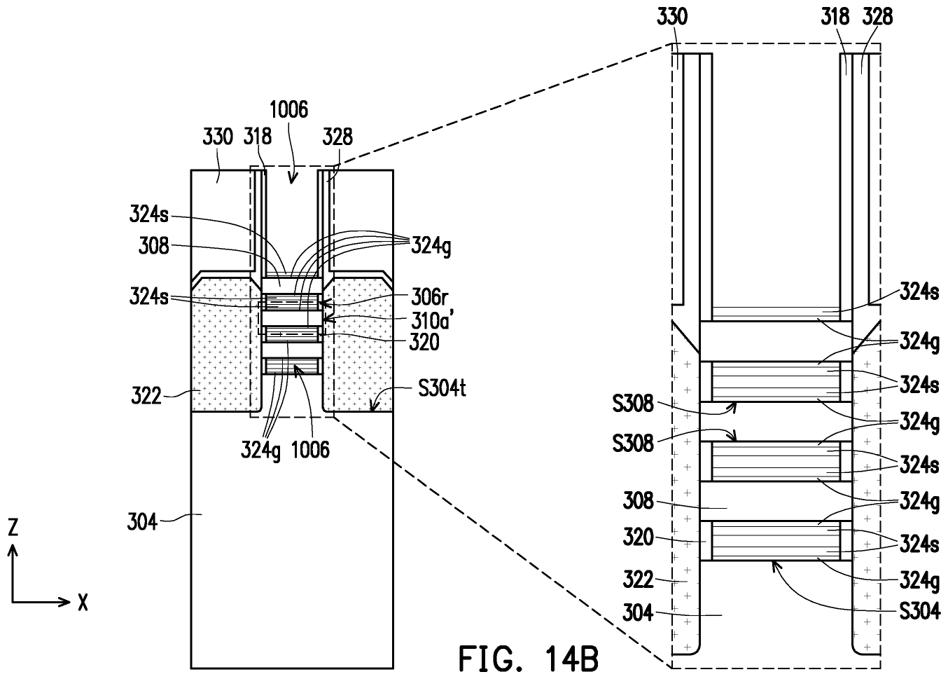

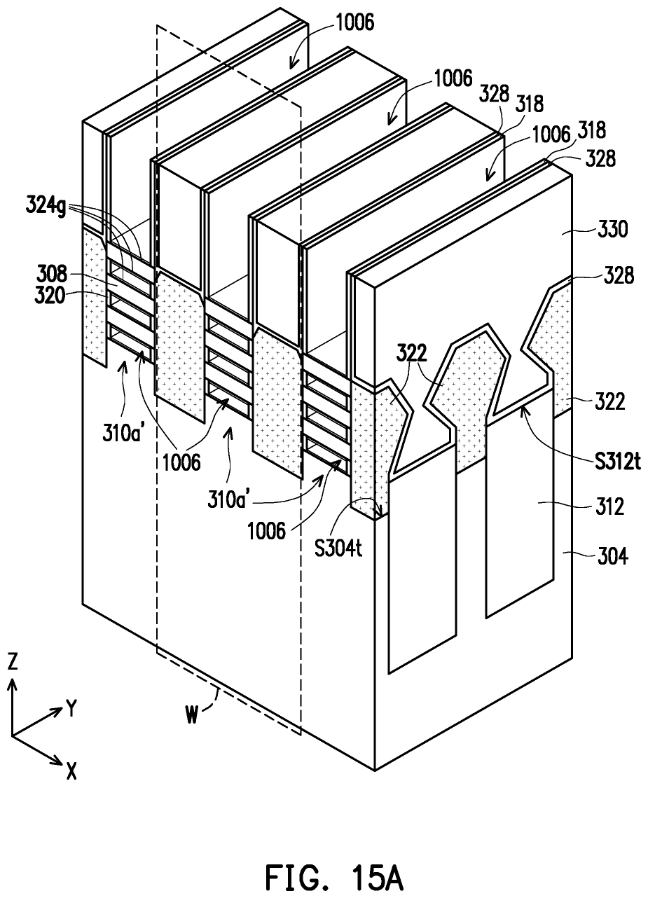

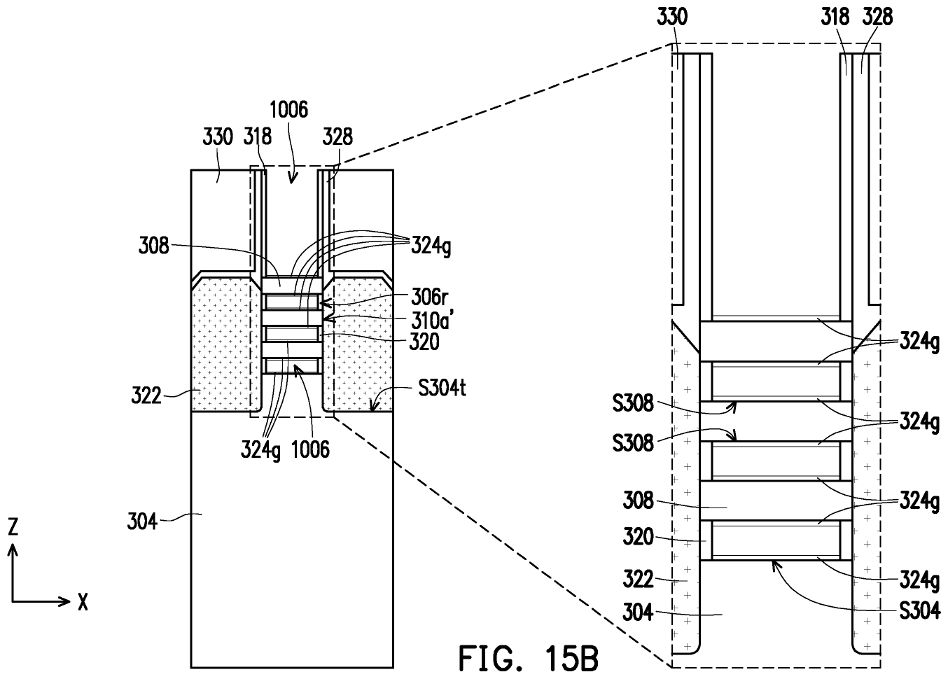

Referring to FIG. 14A and FIG. 14B, in some embodiments, a thermal process is performed on the structure depicted in FIG. 13A and FIG. 13B to transform the semiconductor material 324m into a Ge-containing layer 324g and a Si-containing layer 324s in each cavity 1006, in accordance with a step S111 of the method 100 in FIGS. 19A-19B. For simplicity, the Ge-containing layer 324g and the Si-containing layer 324 in only one of the cavities 1006 will be discussed in greater detail along with FIGS. 14A-14B and 15A-15B as below, however it should understand that same or similar properties/conditions should be also applied to the Ge-containing layers 324g and the Si-containing layers 324 in the rest of the cavities 1006. For example, the Ge-containing layer 324g is disposed at the surfaces S308 of the second semiconductor layers 308 and the exposed surface S304 of the semiconductor substrate 304, and the Si-containing layer 324s is disposed on the Ge-containing layer 324g. In such case, the Ge-containing layer 324g is interposed between the second semiconductor layers 308 and the Si-containing layer 324s and between the semiconductor substrate 304 and the Si-containing layer 324s.

In some embodiments, the Ge-containing layer 324g is a Si₁₋ᵥGeᵥ layer, where v is less than or substantially equal to 1, such as v is in a range of about 0.2 to about 1.0. For example, the Ge-containing layer 324g is a c-SiGe layer, with a composition of c-Si₁₋ᵥGeᵥ, such as v is in a range of about 0.2 to about 1.0. The Ge-containing layer 324g may have a composition of c-Si₁₋ᵥGeᵥ, where v is less than or substantially equal to 1, such as v is greater than or substantially equal to about 0.20, about 0.25, about 0.30, about 0.35, about 0.40, about 0.45, about 0.50, about 0.55, about 0.60, about 0.65, about 0.70, about0.75, about 0.80, about 0.85, about 0.90, about 0.95, or about 1.0. In a non-limiting example, the Ge-containing layer 324g has a composition of c-Si₁₋ᵥGeᵥ, where v is greater than or substantially equal to 0.20 and less than 0.5, such as 0.3≤v<0.5. The Ge-containing layer 324g is a c-Si₁₋ᵥGeᵥ layer, with v is greater than or substantially equal to 0.3, for example. In another non-limiting example, the Ge-containing layer 324g has a composition of c-Si₁₋ᵥGeᵥ, where v is greater than or substantially equal to 0.5 and less than 1.0, where the Ge-containing layer 324g is referred to as a Ge-rich layer. In another non-limiting example, the Ge-containing layer 324g has a composition of c-Si₁₋ᵥGeᵥ, where v is substantially equal to 1.0, where the Ge-containing layer 324g is referred to as a Ge-rich layer and is further considered as a Ge layer or a pure Ge layer. The Ge-containing layer 324g may be a single c-SiGe layer. Alternatively, the Ge-containing layer 324g may be a strained single c-SiGe layer.

In some embodiments, a thickness T324g of the Ge-containing layer 324g is in a range of about 0.1 to about 0.9 of the thickness T324m of the semiconductor material 324m. In some embodiments of which the transistor 300A is a GAA transistor or a nanowire transistor, a thickness T324g of the Ge-containing layer 324g is in a range of about 0.3 nm to about 4.5 nm, such as about 2 nm to about 3 nm. As shown in FIG. 14B, the thickness T324g of the Ge-containing layer 324g may be about 1 nm. Although other values of the thickness of the semiconductor material 324m are possible depending on product and process requirements. In other alternative embodiments of which the transistor 300A is a planar FET transistor or a TFET transistor, a thickness of the Ge-containing layer is in a range of about 0.3 nm to about 27 nm. In further alternative embodiments of which the transistor 300A is a finFET transistor, a thickness of the Ge-containing layer is in a range of about 0.3 nm to about 13.5 nm. As shown in FIG. 14A and FIG. 14B, the Ge-containing layer 324g is conformally disposed on the second semiconductor layers 308 (e.g., the exposed surfaces S308) and the semiconductor substrate 304 (e.g., the exposed surfaces S304) exposed by the cavities 1006, for example.

In some embodiments, the Si-containing layer 324s is a silicon oxide layer, such as a SiO₂ layer. The Si-containing layer 324s is a pure SiO₂ layer, for example. A thickness T324s of the Si-containing layer 324s may be less than the thickness T324m of the semiconductor material 324m. The thickness T324s of the Si-containing layer 324s may be greater than the thickness T324g of the Ge-containing layer 324g. Alternatively, the thickness T324s of the Si-containing layer 324s may be substantially equal to the thickness T324g of the Ge-containing layer 324g. Or alternatively, the thickness T324s of the Si-containing layer 324s may be less than the thickness T324g of the Ge-containing layer 324g. In some embodiments, a thickness T324s of the Si-containing layer 324s is in a range of about 0.9 to about 0.1 of the thickness T324m of the semiconductor material 324m. In some embodiments of which the transistor 300A is a GAA transistor or a nanowire transistor, the thickness T324s of the Si-containing layer 324s is in a range of about 1 nm to about 4.5 nm, such as the thickness T324s of the Si-containing layer 324s is about 3 nm. Although other values of the thickness of the semiconductor material 324m are possible depending on product and process requirements. In other alternative embodiments of which the transistor 300A is a planar FET transistor or a TFET transistor, a thickness of the Si-containing layer is in a range of about 1 nm to about 27 nm. In further alternative embodiments of which the transistor 300A is a finFET transistor, a thickness of the Si-containing layer is in a range of about 1 nm to about 13.5 nm. As shown in FIG. 14A and FIG. 14B, the Si-containing layer 324s is directly disposed on (e.g., in physical contact with) the Ge-containing layer 324g, where the second semiconductor layers 308 are separated from the Si-containing layer 324s through the Ge-containing layer 324g, for example. The Ge-containing layer 324g is directly interposed between the Si-containing layer 324s and the second semiconductor layers 308 and between the Si-containing layer 324s and the semiconductor substrate 304. Due to the presence of the Ge-containing layer 324g, the voltage threshold of a PMOS device, such as the semiconductor device SD1 having the transistor 300A, is reduced. In addition, owing to the Ge-containing layer 324g covering the channel regions (e.g., the second semiconductor layers 308), the compressive strain is further provided to the channel regions, thereby enhancing hole mobility of the channel regions for the PMOS device.

A method of transforming the semiconductor material 324m into the Ge-containing layer 324g and the Si-containing layer 324s may include, but not limited to, performing a thermal process to the semiconductor material 324m so to oxide the semiconductor material 324m, where during the oxidation of the semiconductor material 324m, only silicon atoms react with oxygen atoms to form the Si-containing layer 324s, while germanium atoms are rejected from the Si-containing layer 324s and condensate at the second semiconductor layers 308 (e.g., at S308) and the semiconductor substrate 304 (e.g., at S304) so to form the Ge-containing layer 324g, since the silicon atoms are more reactive to the oxygen atoms than the germanium atoms are. In other words, the germanium atoms do not participate in the oxidation of the semiconductor material 324m. There may be no loss of Ge during the oxidation of the semiconductor material 324m. In some embodiments, the thermal process is performed at an oxygen (O₂) atmosphere at temperatures lower than the melting point of the semiconductor material 324m. For a non-limiting example, the working temperature is less than or substantially equal to 600° C., such as a temperature ranging from about 400° C. to about 600° C. With such temperature range (e.g., less than or substantially equal to 600° C.), changes in the profile of the source/drain regions 322 can be avoid. Since the germanium atoms condensate on the exposed surfaces S308 of the second semiconductor layers 308 and the exposed surfaces S304 of the semiconductor substrate 304 to form the Ge-containing layer 324g, there is no facet epi region to the Ge-containing layer 324g. The Ge-containing layer 324g is conformally formed on the second semiconductor layers 308 and the semiconductor substrate 304 to adopt the topography of the second semiconductor layers 308 and the semiconductor substrate 304. Owing to the Ge-containing layer 324g having no facet epi region, the uniformity and reliability of a gate (e.g., 338 in FIG. 16A and FIG. 16B) of the transistor 300A can be well-controlled, thereby enhancing the performance of the semiconductor device SD1 having the transistor 300A. In addition, the thickness T324g of the Ge-containing layer 324g is controllable by adjusting the process time and the thickness T324m of the semiconductor material 324m, for example.

The thermal process may include an oxidation process, such as a wet or dry oxidation. For a non-limiting example, the thermal process include a rapid thermal oxidation (RTO) for about 0.5 sec to about 1 hour, at a pressure in a range from about 0.1 Torr to about 15,200 Torr, at a temperature in a range less than or substantially equal to 600° C. (such as in a range from about 400° C. to about 600° C.), with a gas flow including from about 0.1 standard cubic centimeters per minute (sccm) to about 50,000 sccm of O₂ and from about 0.1 sccm to about 50,000 sccm of H₂/Ar/N₂ as a carrier gas. However, the disclosure is not limited thereto. For another non-limiting example, the thermal process include a dry furnace oxidation for about 0.5 hours to about 24 hours, at a pressure in a range from about 0.1 Torr to about 15,200 Torr, at a temperature in a range less than or substantially equal to 600° C. (such as in a range from about 400° C. to about 600° C.), with a gas flow including from about 1 sccm to about 40,000 sccm of O₂ and from about 1 sccm to about 40,000 sccm of H₂/Ar/N₂ as a carrier gas. For another non-limiting example, the thermal process include a wet furnace oxidation for about 0.25 hours to about 12 hours, at a pressure in a range from about 0.1 Torr to about 15,200 Torr, at a temperature in a range less than or substantially equal to 600° C. (such as in a range from about 400° C. to about 600° C.), with a gas flow including from about 0.1 sccm to about 40,000 sccm of O₂, a gas flow including from about 0.1 sccm to about 40,000 sccm of H₂O, and from about 0.1 sccm to about 40,000 sccm of H₂/Ar/N₂ as a carrier gas. For another non-limiting example, the thermal process include an in-situ steam generation (ISSG) oxidation for about 0.25 hours to about 12 hours, at a pressure in a range from about 0.1 Torr to about 15,200 Torr, at a temperature in a range less than or substantially equal to 600° C. (such as in a range from about 400° C. to about 600° C.), with a gas flow including from about 0.1 sccm to about 40,000 sccm of O₂, and from about 0.1 sccm to about 40,000 sccm of H₂/Ar/N₂ as a carrier gas. For example, after the thermal process, there is an interface presented between the Ge-containing layer 324g and the Si-containing layer 324s.

Referring to FIG. 15A and FIG. 15B, in some embodiments, the Si-containing layer 324s is removed to accessibly reveal the Ge-containing layer 324g by the cavities 1006, in accordance with a step S112 of the method 100 in FIGS. 19A-19B. For example, the removal of the Si-containing layer 324s includes a selective etching process, where there is a high etching selectivity (e.g., greater than or substantially equal to 10) between SiO₂ and a silicon germanium material, such that the material of the Si-containing layer 324s is selectively removed with respect to the material of the Ge-containing layer 324g. The selective etching process may include a dry etching, a wet etching (e.g., using dHF as an etchant), or a combination thereof. In a non-limiting example, the selective etching process includes an isotropic etching process. In the case, the isotropic etching process of selectively etching can remove the Si-containing layer 324s while leaving the Ge-containing layer 324g and other components (e.g., the ILD layer 330, the dielectric layer 328, the gate spacers 318, and the inner spacers 320) in the current structure substantially intact. For example, the Si-containing layer 324s is removed by performing a SiO₂ removal process. In the embodiments of which the transistor 300A is the GAA device, due to the Si-containing layer 324s is removed and the Ge-containing layer 324g is thin (e.g., a conformally thin continuous layer), a change in the overall volume of the cavities 1006 is considered insignificant (e.g., an insignificantly loss to the overall volume of the cavities 1006 in the formation of the Ge-containing layer 324g), thereby ensuring the process window for forming the gate of the transistor 300A in a sequential process(es). It is appreciated that there is no penalty of sheet-sheet spacing while forming the Ge-containing layer 324g on the channel regions of the transistor 300A included in the semiconductor device SD1, in the disclosure.

Referring to FIG. 16A and FIG. 16B, in some embodiments, interfacial (IL) layers 332, gate dielectric layers 334, and gate electrodes 336 are formed over the Ge-containing layer 324g in the cavities 1006 defined between adjacent gate spacers 318 and the inner spacers 320, in accordance with a step S113 of the method 100 in FIGS. 19A-19B. One interfacial layer 332, one gate dielectric layer 334, and one gate electrode 336 disposed in one cavity 1006 may be collectively referred to as a gate structure 338 of the transistor 300A. That is, the previously shown sacrificial gate structures 50 may be regarded as being replaced by the gate structures 338. Up to here, a plurality of transistors 300A included in the semiconductor device SD1 is manufactured. The transistors 300A respectively include one of the gate structures 338, the second semiconductor layers 308 in this gate structure 338, the Ge-containing layers 324g in this gate structures 338 and interposed between this gate structures 338 and the second semiconductor layers 308, and a pair of source/drain regions 322 at opposite sides of this gate structure 338. In addition, the transistors 300A respectively include may further includes the inner spacers 320 in this gate structure 338 and a pair of gate spacers 318 at the opposite sides of this gate structure 338. The number and configurations of the transistors 300A formed in the semiconductor device SD1 should not be limited by the embodiments or drawings of the disclosure. It is understood that the number and configurations of the transistors 300A may have different material or configurations depending on product designs. The gate structures 338 may be referred to as metal gate structures.

As shown in FIG. 16A and FIG. 16B, the interfacial layers 332 are lining on surfaces of the Ge-containing layers 324g accessibly exposed by the cavities 1006, for example. In the case, the gate dielectric layers 334 are lining on exposed surfaces of the interfacial layers 332, the inner spacers 320 and the gate spacers 318, and the gate electrodes 336 fill the remainder space in these cavities 1006. The interfacial layers 332 may include a dielectric material such as silicon oxide layer or silicon oxynitride. In some embodiments, the interfacial layers 332 may be formed by a deposition process such as ALD, CVD, and/or other suitable deposition methods. The interfacial layers 332 may be adapted to provide a good interface between the semiconductor surface (i.e., the Ge-containing layer covering the second semiconductor layers 308) and a gate insulator (i.e., the gate dielectric layers 334) and to suppress the mobility degradation of the channel carrier of the transistors 300A. A material of the gate dielectric layer 334 may include a high-k dielectric material. In some embodiments, low-k dielectric materials are generally dielectric materials having a dielectric constant greater than about 4, greater than about 12, greater than about 16, or even greater than about 20. Examples of the high-k dielectric material may include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 334 may be one-layer structure or a multi-layer structure of different sublayers. The gate dielectric layer 334 may be referred to as a high-k dielectric layer. A method for forming the gate dielectric layers 334 may include a deposition process, such as a CVD process or an ALD process. A material of the gate electrodes 336 may include polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. A method for forming the gate electrodes 336 may include a deposition process (e.g., a CVD process or an ALD process), a plating process (e.g., an electrical plating process or an electroless plating process) or a combination thereof. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, one or more work function layer (not shown) is formed between each gate dielectric layer 334 and the overlying gate electrode 336. A material of the work function layer may include p-type work function metals or n-type work function metals. For example, the p-type work function metals include TiN, TaN, Ru, Mo, Al, WN, ZrSi₂, MoSi₂, TaSi₂, NiSi₂, WN, other suitable p-type work function materials, or combinations thereof. For example, the n-type work function metals include Ti, Ag, TaAl, TaAlC, TiAlN, TaC, TaCN, TaSiN, Mn, Zr, other suitable n-type work function materials, or combinations thereof. In some embodiments, the method of forming the work function layer includes performing at least one suitable deposition technique, such as CVD (e.g., PECVD), ALD (e.g., remote plasma atomic layer deposition (RPALD), plasma enhanced atomic layer deposition (PEALD), molecular beam deposition (MBD), or the like. The work function layer may serve the purpose of adjusting threshold voltage (Vt) of the transistors 300A.

Referring to FIG. 17A and FIG. 17B, in some embodiments, an ILD layer 340 is formed over the transistors 300A and extends onto the illustrated top surfaces of the ILD layer 330 and the dielectric layer 328. The formation and material of the ILD layer 340 is similar to or substantially identical to the formation and material of the ILD layer 330 as described in FIG. 11A and FIG. 11B, and thus are not repeated herein for brevity. Thereafter, a plurality of though openings (not labeled) may be formed in the ILD layer 340 and further extend into the ILD layer 330 and the dielectric layer 328 to expose (e.g., accessibly reveal) portions of the source/drain regions 322, as shown in FIGS. 17A and 17B. The through openings may be formed by patterning the ILD layer 340, the ILD layer 330 and the dielectric layer 328 with lithography and etching processes. The etching process may include a dry etching, a wet etching, or a combination thereof.

In some embodiments, after forming the through openings in the ILD layer 340, the ILD layer 330 and the dielectric layer 328, a plurality of contact plugs 344 are formed in the through openings to couple with the source/drain regions 322. The contact plugs 344 may be referred to as metal contacts or metallic contacts to the source/drain regions 322. For example, the contact plugs 344 electrically coupled to the source/drain regions 322 are referred to as source/drain contacts. In some embodiments, the contact plugs 344 may include ruthenium (Ru), cobalt (Co), copper (Cu), titanium (Ti), titanium nitride (TiN), tantalum (Ta), tantalum nitride (TaN), molybdenum (Mo), nickel (Ni), a combination of thereof, or the like. The contact plugs 344 may be formed by, for example, plating such as electroplating or electroless plating, CVD such as PECVD, ALD, and PVD, a combination thereof, or the like. Seed layers (not shown) may be optionally formed before forming the contact plugs 344 to line sidewalls and illustrated bottoms of the through openings. That is, for example, each of the seed layers covers an illustrated bottom surface and sidewalls of a respective one of the contact plugs 344. In some embodiments, each of the seed layers is a metal layer, which may be a single layer or a composite layer comprising a plurality of sub-layers formed of different materials. The seed layers are formed using, for example, PVD or the like. In one embodiment, the seed layers may be omitted.

Barrier layer or adhesive layers 342 may be optionally formed before forming the contact plugs 344. In some embodiments, the barrier layer or adhesive layers 342 may be optionally formed between the contact plugs 344 and the ILD layer 340, between the contact plugs 344 and the ILD layer 330, and between the contact plugs 344 and the dielectric layer 328. Owing to the additional barrier layer or adhesive layers 342, it is able to ensure the adhesion between the contact plugs 344 and the ILD layer 340, between the contact plugs 344 and the ILD layer 330, and between the contact plugs 344 and the dielectric layer 328. As shown in FIG. 17A and FIG. 17B, the barrier layer or adhesive layers 342 line on the sidewalls of the contact plugs 344, where the contact plugs 344 respectively stand on the source/drain regions 322, for example. The additional barrier layer or adhesive layers 342 may include Ti, TiN, Ta, TaN, a combination thereof, a multilayer thereof, or the like, and may be formed using CVD, ALD, PVD, a combination thereof, or the like. In an alternative embodiment of which the seed layer is included, the additional barrier layer or adhesive layer 342 is interposed between the seed layer and the ILD layer 340, between the seed layer and the ILD layer 330 and between the seed layer and the dielectric layer 328, where the seed layer is interposed between the contact plugs 344 and the additional barrier layer or adhesive layer 342. In the embodiments of the seed layer is presented, owing to the additional barrier layer or adhesive layer 342, it is able to prevent the seed layer and/or the contact plugs 344 from diffusing to the underlying layers and/or the surrounding layers. In one embodiment, the additional barrier layer or adhesive layer 342 may be omitted. As shown in FIG. 17A, sidewalls of the contact plugs 344 may be substantially vertical sidewalls. The disclosure is not limited thereto, alternatively, the sidewalls of the contact plugs 344 may be slant sidewalls or step-shaped sidewalls.

In some embodiments, a plurality of conductive vias 348 are formed over the transistors 300A and the contact plugs 344, and a dielectric layer 346 are formed to laterally cover the conductive vias 348. As shown in FIG. 17A and FIG. 17B, illustrated top surface of the conductive vias 348 may be accessibly revealed by the dielectric layer 346 for electrical connection with later-formed elements, such as conductive features in a later-formed interconnect or interconnection structure. The dielectric layer 346 may be referred to as an ILD layer, while the conductive vias 348 may be referred to as contact vias or metallic vias. For example, some of the conductive vias 348 are electrically connected to the contact plugs 344 connected to the source/drain regions 322, and some of the conductive vias 348 are electrically connected to the gate electrodes 336 of the gate structure 338. The conductive vias 348 electrically connected to the contact plugs 344 connected to the source/drain regions 322 may be referred to as source/drain contacts, and the conductive vias 348 electrically connected to the gate electrodes 336 of the gate structure 338 may be referred to as gate contacts.

In some embodiments, a material of the dielectric layer 346 includes polyimide, epoxy resin, acrylic resin, phenol resin, BCB, polybenzoxazole (PBO), or any other suitable polymer-based dielectric material. The dielectric layer 346, for example, may be formed by suitable fabrication techniques such as spin-on coating, CVD, PECVD, or the like. In some embodiments, the conductive vias 348 may include copper (Cu), copper alloys, nickel (Ni), aluminum (Al), manganese (Mn), magnesium (Mg), silver (Ag), gold (Au), tungsten (W), a combination of thereof, or the like. Seed layers (not shown) may be optionally formed before forming the conductive vias 348 to line an illustrated bottom surface and sidewalls of a respective one of the conductive vias 348 or to line an illustrated bottom surface of a respective one of the conductive vias 348. In some embodiments, each of the seed layers is a metal layer, which may be a single layer or a composite layer comprising a plurality of sub-layers formed of different materials. The seed layers are formed using, for example, PVD or the like. In one embodiment, the seed layers may be omitted. The conductive vias 348 may be formed by, for example, plating such as electroplating or electroless plating, CVD such as PECVD, ALD, and PVD, a combination thereof, or the like. In a non-limiting example, the transistors 300A, the contact plugs 344 and the conductive vias 348 are formed in a front-end-of-line (FEOL) process. However, it is also appreciated that the transistors 300A may be formed in a FEOL process, while the contact plugs 344 and the conductive vias 348 may be formed in a middle-end-of-line (MEOL) process.

Thereafter, an interconnection structure 200 may be formed over the conductive vias 348 and the dielectric layer 346, in accordance with a step S114 of the method 100 in FIGS. 19A-19B. For example, the interconnection structure 200 may include a stack 230 of dielectric layers and interconnections (210a, 220a, and 210b) formed in the stack 230 of dielectric layers. The interconnections (210a, 220a, and 210b) are electrically coupled to the transistors 300A through the conductive vias 348 and the dielectric layer 346. As shown in FIG. 17A and FIG. 17B, the interconnections includes conductive layers 210a, 210b and conductive vias 220a alternately stacked upon one another (along the direction Z), for example. The conductive layers 210a, 210b are connected and electrically coupled to each other through the conductive 220a, and the conductive layer 210a is connected and electrically coupled to the conductive vias 348, so to provide routing function to the transistors 300A of the semiconductor device SD1. Up to here, the semiconductor device SD1 having the transistor 300A is manufactured.

The formation and material of each of the conductive layers 210a, 210b and the conductive vias 220a are similar to or substantially identical to the formation and material of the conductive vias 348, the formation and material of the dielectric layers included in the stack 230 are similar to or substantially identical to the formation and material of the dielectric layer 346, and thus are not repeated herein for brevity. In the disclosure, the interconnection structure 200 is formed in a back-end-of-line (BEOL) process. The interconnection structure 200 may be referred to as a front-side interconnect, a front-side interconnection, or a front-side interconnection structure to provide routing functions to the transistors 300A and/or other devices formed underneath thereto. For illustrative purpose, only two build-up layers (e.g., a first build-up layer including the conductive layer 210a, the conductive vias 220a and a portion of the stack 230a laterally covering the conductive layer 210a and conductive vias 220a, and a second build-up layer including the conductive layer 210b and a portion of the stack 230a laterally covering the conductive layer 210b) are shown in the interconnection structure 200, however the disclosure is not limited to the embodiments and/or drawings. The interconnection structure 200 may incudes one or more than one first build-up layer and one or more than one second build-up layer alternatively stacked along the direction Z.

FIG. 18A is a schematic three-dimensional view of a semiconductor device SD2 in accordance with some other embodiments of the disclosure. FIG. 18B is a schematic, enlarged cross-sectional view of a portion of the semiconductor device SD2 outlined in a dashed box V as shown in FIG. 18A. The elements similar to or substantially the same as the elements described previously will use the same reference numbers, and certain details or descriptions (e.g., the materials, formation processes, positioning configurations, electrical connections, etc.) of the same elements would not be repeated herein. In some embodiments, the channel regions may be trimmed before forming the Ge-containing layers. The semiconductor device SD2 depicted in FIGS. 18A-18B is similar to the semiconductor device SD1 depicted in FIGS. 17A-17B. Only the difference therebetween will be described, the same or the like parts would not be repeated again.

Referring to FIG. 18A and FIG. 18B, in some embodiments, the semiconductor device SD2 includes a plurality of transistors 300B and an interconnection structure 200 interconnecting therebetween. For example, the transistors 300B respectively include one gate structure 338, a plurality of trimmed second semiconductor layers 308′ in the gate structure 338 and stacked along a direction (e.g., Z), a Ge-containing layer 324g in the gate structures 338 and interposed between the gate structures 338 and the trimmed second semiconductor layers 308′, and a pair of source/drain regions 322 at opposite sides of the gate structure 338. In addition, the transistors 300B respectively include may further includes the inner spacers 320 in the gate structure 338 and a pair of gate spacers 318 at the opposite sides of the gate structure 338. The inner spacers 320 and the trimmed second semiconductor layer 308′ are arranged alternatively along the direction Z. The number and configurations of the transistors 300B formed in the semiconductor device SD2 should not be limited by the embodiments or drawings of the disclosure. It is understood that the number and configurations of the transistors 300B may have different material or configurations depending on product designs. As shown in FIG. 18B, a thickness of a central portion of each of the second semiconductor layers 308′ is less than a thickness of ends potions of the respective one of the second semiconductor layers 308′. In other words, there is more space for forming the gate structures 338. Due to the trimmed second semiconductor layers 308′, the process window of the gate structures 338 are increased, thereby facilitate the manufacture of the transistors 300B included in the semiconductor device SD2.

The formation of the semiconductor device SD2 may include, but not limited to, performing a trimming process on the second semiconductor layers 308 of the structure depicted in FIG. 12A and FIG. 12B to form a plurality of trimmed second semiconductor layers 308′ (in accordance with a step S109 of the method 100 in FIG. 19A and FIG. 19B), and then performing the processes described in FIGS. 13A-13B, 14A-14B, 15A-15A, 16A-16B, and 17A-17B on the structure having the trimmed second semiconductor layers 308′ to form the semiconductor device SD2. During trimming the second semiconductor layers 308, portions of the semiconductor substrate 304 exposed by the cavities 1006 are also trimmed, for example. The trimming process may include an etching process such as a dry etching, a wet etching, or a combination thereof.

In accordance with some embodiments, a method of manufacturing a semiconductor device includes the following steps: forming a stack of semiconductor layers and sacrificial layers alternately arranged over a substrate along a vertical direction; patterning the stack to form a stacking structure on the substrate, the stacking structure extending along a first horizontal direction; disposing a sacrificial gate structure on the substrate, where the sacrificial gate structure is extending along a second horizontal direction intersected with the first horizontal direction and covers a portion of the stacking structure; removing portions of the stacking structure not overlapped with the sacrificial gate structure; disposing source/drain regions at opposite sides of the sacrificial gate structure, where the semiconductor layers in the remained stacking structure connect between the source/drain regions; removing the sacrificial gate structure and rest of the sacrificial layers to form a cavity accessibly revealing the semiconductor layers in the remained stacking structure; forming a semiconductor material to cover the semiconductor layers in the remained stacking structure being accessibly revealed by the cavity; performing a thermal process to transfer the semiconductor material into a Si-containing layer and a Ge-containing layer, where the Si-containing layer is disposed over the semiconductor layers being accessibly revealed by the cavity, and the Ge-containing layer is interposed between the Si-containing layer and the semiconductor layers in the remained stacking structure; removing the Si-containing layer; and forming a gate structure in the cavity and over the remained stacking structure.

In accordance with some embodiments, a method of manufacturing a semiconductor device includes the following steps: forming a plurality of transistors, comprising: forming a stack of first semiconductor layers and second semiconductor layers alternately arranged along a vertical direction; patterning the stack to form a plurality of stacking structures, the plurality of stacking structures extending along a first horizontal direction; disposing a plurality of dummy gate structures on the plurality of stacking structures, where the plurality of dummy gate structures are extending along a second horizontal direction intersected with the first horizontal direction and cover portions of the plurality of stacking structures; removing portions of the plurality of stacking structures not overlapped with the plurality of dummy gate structures; laterally recessing the first semiconductor layers to form a plurality of first recesses; forming inner spacers in the plurality of first recesses, the inner spacers respectively connecting two adjacent second semiconductor layers in the vertical direction; disposing source/drain regions at opposite sides of the plurality of the dummy gate structures, where the second semiconductor layers connect between the source/drain regions in the first horizontal direction; removing the plurality of dummy gate structures and rest of the first semiconductor layers to form a plurality of cavities exposing the second semiconductor layers; selectively forming a layer of SiGe material to cover the second semiconductor layers exposed by the plurality of cavities; oxidizing the layer of SiGe material to form a Si-containing layer and a Ge-containing layer over the second semiconductor layers, where the Ge-containing layer is interposed between the Si-containing layer and the second semiconductor layers; removing the Si-containing layer; and forming a plurality of gate structures in the cavities and over the plurality of stacking structures; and forming an interconnection structure over the plurality of transistors, where the plurality of transistors are electrically coupled through the interconnection structure.

In accordance with some embodiments, a semiconductor device includes two source/drain features, one or more channel layers, a gate structure, and a Ge-containing layer. The two source/drain features are laterally arranged to each other. The one or more channel layers connect the two source/drain features. The gate structure engages the one or more channel layers and interposes between the two source/drain features. The Ge-containing layer interposes between the one or more channel layers and the gate structure, where the one or more channel layers are enclosed by the Ge-containing layer and the two source/drain features, and the Ge-containing layer is free of facet regions.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A method of manufacturing a semiconductor device, comprising:
forming a stack of semiconductor layers and sacrificial layers alternately arranged over a substrate along a vertical direction;
patterning the stack to form a stacking structure on the substrate, the stacking structure extending along a first horizontal direction;
disposing a sacrificial gate structure on the substrate, wherein the sacrificial gate structure is extending along a second horizontal direction intersected with the first horizontal direction and covers a portion of the stacking structure;
removing portions of the stacking structure not overlapped with the sacrificial gate structure;
disposing source/drain regions at opposite sides of the sacrificial gate structure, the semiconductor layers in the remained stacking structure connecting between the source/drain regions;
removing the sacrificial gate structure and rest of the sacrificial layers to form a cavity accessibly revealing the semiconductor layers in the remained stacking structure;
forming a semiconductor material to cover the semiconductor layers in the remained stacking structure being accessibly revealed by the cavity;
performing a thermal process to transfer the semiconductor material into a Si-containing layer and a Ge-containing layer, wherein the Si-containing layer is disposed over the semiconductor layers being accessibly revealed by the cavity, and the Ge-containing layer is interposed between the Si-containing layer and the semiconductor layers in the remained stacking structure;
removing the Si-containing layer; and
forming a gate structure in the cavity and over the remained stacking structure.

2. The method of claim 1, wherein the cavity further accessibly reveals the substrate overlapped with the remained stacking structure, wherein:
forming the semiconductor material to cover the semiconductor layers in the remained stacking structure being accessibly revealed by the cavity further comprises forming the semiconductor material to cover the substrate overlapped with the remained stacking structure being accessibly revealed by the cavity, and
the Si-containing layer is further disposed over the substrate overlapped with the remained stacking structure being accessibly revealed by the cavity, and the Ge-containing layer is further interposed between the Si-containing layer and the substrate overlapped with the remained stacking structure being accessibly revealed by the cavity.

3. The method of claim 1, further comprising:
globally disposing a dielectric layer over the substrate to cover the sacrificial gate structure and the stacking structure; and
patterning the dielectric layer to form a pair of gate spacers at the two opposite sides of the sacrificial gate structure,
wherein:
removing portions of the stacking structure not overlapped with the sacrificial gate structure comprises removing portions of the stacking structure not overlapped with the sacrificial gate structure and the pair of gate spacers.

4. The method of claim 1, prior to removing the sacrificial gate structure and the rest of the sacrificial layers, further comprising:
conformally forming an etching stop layer over the source/drain regions and the sacrificial gate structure;
forming an isolation structure over the substrate to cover the etching stop layer, the source/drain regions, and the sacrificial gate structure; and
performing a planarization process to accessibly reveal the sacrificial gate structure.

5. The method of claim 1, prior to disposing the source/drain regions and after removing the portions of the stacking structure not overlapped with the sacrificial gate structure, further comprising:
laterally recessing the sacrificial layers included in the remained stacking structure to form a plurality of first recesses; and
forming inner spacers in the plurality of first recesses.

6. The method of claim 1, wherein forming the semiconductor material to cover the semiconductor layers in the remained stacking structure being accessibly revealed by the cavity comprises forming a Si_{1-w}Ge_{w} layer by selective epitaxial grown to cover the semiconductor layers in the remained stacking structure being accessibly revealed by the cavity, and w is in a range of about 0.1 to about 0.5.

7. The method of claim 1, wherein performing the thermal process comprises performing an oxidation treatment under a temperature being less than or substantially equal to 600° C.

8. The method of claim 1, prior to forming the semiconductor material to cover the semiconductor layers and after removing the sacrificial gate structure and the rest of the sacrificial layers, further comprising:
trimming the semiconductor layers.

9. A method of manufacturing a semiconductor device, comprising:
forming a plurality of transistors, comprising:
forming a stack of first semiconductor layers and second semiconductor layers alternately arranged along a vertical direction;
patterning the stack to form a plurality of stacking structures, the plurality of stacking structures extending along a first horizontal direction;
disposing a plurality of dummy gate structures on the plurality of stacking structures, wherein the plurality of dummy gate structures are extending along a second horizontal direction intersected with the first horizontal direction and cover portions of the plurality of stacking structures;
removing portions of the plurality of stacking structures not overlapped with the plurality of dummy gate structures;
laterally recessing the first semiconductor layers to form a plurality of first recesses;
forming inner spacers in the plurality of first recesses, the inner spacers respectively connecting two adjacent second semiconductor layers in the vertical direction;
disposing source/drain regions at opposite sides of the plurality of the dummy gate structures, the second semiconductor layers connecting between the source/drain regions in the first horizontal direction;
removing the plurality of dummy gate structures and rest of the first semiconductor layers to form a plurality of cavities exposing the second semiconductor layers;
selectively forming a layer of SiGe material to cover the second semiconductor layers exposed by the plurality of cavities;
oxidizing the layer of SiGe material to form a Si-containing layer and a Ge-containing layer over the second semiconductor layers, wherein the Ge-containing layer is interposed between the Si-containing layer and the second semiconductor layers;
removing the Si-containing layer; and
forming a plurality of gate structures in the cavities and over the plurality of stacking structures; and
forming an interconnection structure over the plurality of transistors, wherein the plurality of transistors are electrically coupled through the interconnection structure.

10. The method of claim 9, wherein oxidizing the layer of SiGe material to form the Si-containing layer and the Ge-containing layer over the second semiconductor layers comprises oxidizing the layer of SiGe material to form a SiO₂ layer and a Ge layer over the second semiconductor layers, wherein the Ge layer is interposed between the SiO₂ layer and the second semiconductor layers.

11. The method of claim 9, wherein:
selectively forming the layer of SiGe material to cover the second semiconductor layers exposed by the plurality of cavities comprises forming a Si_{1-w}Ge_{w} layer by selective epitaxial grown to cover the second semiconductor layers, and w is in a range of about 0.1 to about 0.5, and
the Ge-containing layer is formed to have a composition of Si₁₋ᵥGeᵥ, and v is about twice of w.

12. The method of claim 9, prior to selectively forming the layer of SiGe material to cover the second semiconductor layers exposed by the plurality of cavities and after removing the plurality of dummy gate structures and rest of the first semiconductor layers, further comprising:
trimming the second semiconductor layers, wherein a thickness of a central portion of each of the second semiconductor layers is less than a thickness of ends potions thereof.

13. The method of claim 9, wherein removing the Si-containing layer comprising performing a selective etching process to removing only the Si-containing layer.

14. A semiconductor device, comprising:
two source/drain features, laterally arranged to each other;
one or more channel layers, connecting the two source/drain features;
a gate structure, engaging the one or more channel layers and interposing the two source/drain features; and
a Ge-containing layer, interposing the one or more channel layers and the gate structure, wherein the one or more channel layers are enclosed by the Ge-containing layer and the two source/drain features, and the Ge-containing layer is free of facet regions.

15. The semiconductor device of claim 14, wherein the Ge-containing layer comprises a crystal Si₁₋ᵥGeᵥ layer, and v is in a range of about 0.2 to about 1.0.

16. The semiconductor device of claim 14, wherein the Ge-containing layer comprises a Si₁₋ᵥGeᵥ layer, and v is greater than or substantially equal to 0.5 and less than 1.0.

17. The semiconductor device of claim 14, wherein the Ge-containing layer comprises a pure Ge layer.

18. The semiconductor device of claim 14, wherein the Ge-containing layer is a conformal layer in contact with a surface of the one or more channels and the gate structure.

19. The semiconductor device of claim 14, wherein a thickness of a central portion of one or more channel layers is less than a thickness of ends potions of a respective one of one or more channel layers.

20. The semiconductor device of claim 14, further comprising:
an interconnect structure, over the gate structure, the interconnect structure being electrically coupled to the two source/drain features and the gate structure.
